(19) United States
(12) Patent Application Publication
(10) Pub. No.: US 2025/0081775 A1
(43) Pub. Date: Mar. 6, 2025

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yuanjie XU, Beijing (CN); Ming HU, Beijing (CN); Taofeng XIE, Beijing (CN); Haodi LIU, Beijing (CN)

(21) Appl. No.: 18/726,797

(22) PCT Filed: May 6, 2023
(86) PCT No.: PCT/CN2023/092583

§ 371 Date: Jul. 4, 2024

(30) Foreign Application Priority Data
Jun. 20, 2022 (CN) 202210699653.8

(51) Int. Cl. H10K 59/131; H10K 59/124

(52) U.S. Cl. CPC H10K 59/131; H10K 59/124

(57) ABSTRACT

A display substrate, comprising: a base; and a circuit structure layer arranged on the base. The base comprises a display region; and a peripheral region located on the periphery of the display region. The display region comprises a first display area and a second display area, the first display area at least partially surrounds the second display area. The circuit structure layer comprises a plurality of pixel circuits, a plurality of initial signal lines, and at least one electrostatic conduction line. The plurality of initial signal lines are electrically connected to the plurality of pixel circuits and extend in a first direction, the electrostatic conduction line extends in a second direction. The plurality of pixel circuits are located in first display area, the plurality of initial signal lines are located at least in first display area. The electrostatic conduction line is electrically connected to at least two initial signal lines.

### CROSS-REFERENCE TO RELATED APPLICATIONS

The present application is a U.S. National Phase Entry of International Application No. PCT/CN2023/092583 having an international filing date of May 6, 2023, which claims priority to Chinese Patent Application No. 202210699653.8, filed to the CNIPA on Jun. 20, 2022. The above-identified applications are hereby incorporated herein by reference in their entireties.

### TECHNICAL FIELD

The present disclosure relates to, but is not limited to, the field of display technologies, in particular to a display substrate and a display apparatus.

### BACKGROUND

Organic Light Emitting Diodes (OLEDs) and Quantum-dot Light Emitting Diodes (QLEDs) are active light emitting display devices, and have advantages of self-illumination, a wide viewing angle, a high contrast ratio, low power consumption, an extremely high reaction speed, lightness and thinness, flexibility, and low cost, etc. An under display camera technology is a brand-new technology proposed to increase a screen-to-body ratio of a display device.

### SUMMARY

The following is a summary of subject matters described herein in detail. This summary is not intended to limit the protection scope of claims.

Embodiments of the present disclosure provide a display substrate and a display apparatus.

In one aspect, a display substrate is provided in an embodiment of the present disclosure, which includes a base substrate and a circuit structure layer located on the base substrate. The base substrate includes a display region, and a peripheral region located at a periphery of the display region; wherein the display region comprises a first display region and a second display region, and the first display region at least partially surrounds the second display region. The circuit structure layer includes a plurality of pixel circuits, a plurality of initial signal lines, and at least one electrostatic conductive line. The plurality of initial signal lines are electrically connected with the plurality of pixel circuits and extend along a first direction, the at least one electrostatic conductive line extends along a second direction, and the first direction intersects with the second direction. The plurality of pixel circuits are located in the first display region, and the plurality of initial signal lines are at least located in the first display region; the at least one electrostatic conductive line is electrically connected with at least two initial signal lines.

In some exemplary implementations, a plurality of pixel circuits arranged along the first direction are one row of pixel circuits. The circuit structure layer further comprises a plurality of first signal lines extending along the first direction and electrically connected with the row of pixel circuits. An orthographic projection of the at least one electrostatic conductive line on the base substrate is overlapped with orthographic projections of the plurality of first signal lines on the base substrate.

In some exemplary implementations, the at least one electrostatic conductive line is located on a side of the plurality of first signal lines close to the base substrate, and the plurality of first signal lines are located on a side of the plurality of initial signal lines close to the base substrate.

In some exemplary implementations, in a direction perpendicular to the display substrate, a circuit structure layer of the first display region at least comprises a semiconductor layer, a first conductive layer, and a second conductive layer, that are sequentially disposed on the base substrate; the semiconductor layer comprises active layers of transistors of the plurality of pixel circuits; the first conductive layer comprises gates of the transistors of the plurality of pixel circuits, and first capacitor plates of storage capacitors of the plurality of pixel circuits; and the second conductive layer comprises second capacitor plates of the storage capacitors of the plurality of pixel circuits. The at least one electrostatic conductive line is located in the semiconductor layer, at least two first signal lines are located in the first conductive layer, and the plurality of initial signal lines are located in the second conductive layer.

In some exemplary implementations, the plurality of initial signal lines comprise at least one first initial signal line, and at least one second initial signal line. The at least one electrostatic conductive line comprises at least one first electrostatic conductive line. A first initial signal line and a second initial signal line that are electrically connected with pixel circuits in a same row are electrically connected with a same first electrostatic conductive line.

In some exemplary implementations, the first electrostatic conductive line is located on a side of the first initial signal line and the second initial signal line close to the base substrate. One end of the first electrostatic conductive line is electrically connected with the first initial signal line through a first connection electrode, and another end of the first electrostatic conductive line is electrically connected with the second initial signal line through a second connection electrode; the first connection electrode and the second connection electrode are structures in a same layer, and are located on a side of the first initial signal line and the second initial signal line away from the base substrate.

In some exemplary implementations, an orthographic projection of the first electrostatic conductive line on the base substrate is overlapped with orthographic projections of two first signal lines on the base substrate, the two first signal lines comprise a first scan line electrically and a light emitting control line that are electrically connected with pixel circuits in a same row.

In some exemplary implementations, the plurality of initial signal lines comprise a plurality of first initial signal lines and a plurality of second initial signal lines. The at least one electrostatic conductive line comprises a second electrostatic conductive line and a third electrostatic conductive line. The second electrostatic conductive line is electrically connected with the plurality of first initial signal lines, and the third electrostatic conductive line is electrically connected with the plurality of second initial signal lines.

In some exemplary implementations, the second electrostatic conductive line and the third electrostatic conductive line are structures in a same layer, and are located on a side of the first initial signal line and the second initial signal line close to the base substrate. The second electrostatic conductive line is electrically connected with the first initial signal line through a third connection electrode, and the third electrostatic conductive line is electrically connected with the second initial signal line through a fourth connection electrode; the third connection electrode and the fourth connection electrode are structures in a same layer, and are located on a side of the first initial signal line and the second initial signal line away from the base substrate.

In some exemplary implementations, an orthographic projection of a second electrostatic conductive line connected between two adjacent first initial signal lines on the base substrate is overlapped with orthographic projections of three first signal lines on the base substrate. An orthographic projection of a third electrostatic conductive line connected between two adjacent second initial signal lines on the base substrate is overlapped with orthographic projections of three first signal lines on the base substrate.

In some exemplary implementations, the at least one electrostatic conductive line is located on a side of the plurality of initial signal lines away from the base substrate.

In some exemplary implementations, the at least one electrostatic conductive line is located in the peripheral region.

In some exemplary implementations, the display substrate further includes a light emitting structure layer located on a side of the circuit structure layer away from the base substrate; the light emitting structure layer comprises a plurality of first light emitting elements located in the first display region, and a plurality of second light emitting elements located in the second display region; the plurality of pixel circuits comprise a plurality of first pixel circuits, and a plurality of second pixel circuits; at least one first pixel circuit of the plurality of first pixel circuits is electrically connected with at least one first light emitting element of the plurality of first light emitting elements, and at least one second pixel circuit of the plurality of second pixel circuits is electrically connected with at least one second light emitting element of the plurality of second light emitting elements.

In some exemplary implementations, the light emitting structure layer comprises an anode layer, and an anode layer of the second display region comprises an anode of a second light emitting element; the anode of the second light emitting element has a bottom, and a sidewall extending from the bottom toward a side away from the base substrate.

In some exemplary implementations, the display substrate further includes at least one first organic insulation layer between the light emitting structure layer and the circuit structure layer, wherein a first organic insulation layer of the second display region has at least one first anode groove. An orthographic projection of the anode of the second light emitting element on the base substrate covers an orthographic projection of the first anode groove of the first organic insulation layer on the base substrate. The light emitting structure layer further comprises a pixel definition layer located on a side of the anode layer away from the base substrate, wherein the pixel definition layer is provided with a pixel opening exposing a surface of the anode of the second light emitting element. The orthographic projection of the first anode groove of the first organic insulation layer on the base substrate covers an orthographic projection of the pixel opening on the base substrate.

In some exemplary implementations, the light emitting structure layer further comprises a pixel definition layer, at least a partition of the anode layer is located on a side of the pixel definition layer away from the base substrate; the pixel definition layer is provided with a pixel opening, and the orthographic projection of the anode of the second light emitting element on the base substrate covers an orthographic projection of the pixel opening on the base substrate.

In some exemplary implementations, the display substrate further comprises a first organic insulation layer located on a side of the anode layer close to the base substrate and in contact with the anode layer, and the first organic insulation layer is provided with at least one annular groove in the second display region. An orthographic projection of the anode of the second light emitting element on the base substrate covers an orthographic projection of the annular groove of the first organic insulation layer on the base substrate.

In some exemplary implementations, the first organic insulation layer is further provided with a plurality of assisted holes within the annular groove, and the orthographic projection of the anode of the second light emitting element on the base substrate covers orthographic projections of the plurality of assisted holes within the annular groove on the base substrate.

In another aspect, a display apparatus is provided in an embodiment of the present disclosure, which includes the aforementioned display substrate.

In some exemplary implementations, the display apparatus further includes a sensor located on a side of a non-display face of the display substrate, wherein an orthographic projection of the sensor on the display substrate is overlapped with the second display region of the display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3 is a working timing diagram of the pixel circuit shown in FIG. 2.

FIG. 4 is a schematic diagram of a partition of a display substrate according to at least one embodiment of the present disclosure.

FIG. 5 is an enlarged schematic diagram of a partition of a circuit structure layer of the region CC in FIG. 1.

FIG. 6A is a cross-sectional view of a partition taken along a Q-Q′ direction in FIG. 5.

FIG. 6B is a cross-sectional view of a partition taken along an R-R′ direction in FIG. 5.

FIG. 7A is a schematic diagram of the circuit structure layer after a semiconductor layer is formed in FIG. 5.

FIG. 7B is a schematic diagram of the circuit structure layer after a first conductive layer is formed in FIG. 5.

FIG. 7C is a schematic diagram of the circuit structure layer after a second conductive layer is formed in FIG. 5.

FIG. 7D is a schematic diagram of the circuit structure layer after a third insulation layer is formed in FIG. 5.

FIG. 7E is a schematic diagram of the circuit structure layer after a third conductive layer is formed in FIG. 5.

FIG. 7F is a schematic diagram of the third conductive layer in FIG. 7E.

FIG. 7G is a schematic diagram of the circuit structure layer after a fifth insulation layer is formed in FIG. 5.

FIG. 8A is another enlarged schematic diagram of a partition of a circuit structure layer of the region CC in FIG. 1.

FIG. 8B is a schematic diagram of the circuit structure layer after a semiconductor layer is formed in FIG. 8A.

FIG. 8C is a schematic diagram of the circuit structure layer after a first conductive layer is formed in FIG. 8A.

FIG. 8D is a schematic diagram of the circuit structure layer after a second conductive layer is formed in FIG. 8A.

FIG. 8E is a schematic diagram of the circuit structure layer after a third insulation layer is formed in FIG. 8A.

FIG. 8F is a schematic diagram of the circuit structure layer after a third conductive layer is formed in FIG. 8A.

FIG. 9A is another enlarged schematic diagram of a partition of a circuit structure layer of the region CC in FIG. 1.

FIG. 9B is a schematic diagram of the circuit structure layer after a third conductive layer is formed in FIG. 9A.

FIG. 9C is a schematic diagram of the third conductive layer in FIG. 9B.

FIG. 10 is a schematic sectional view of a partition of a display substrate according to at least one embodiment of the present disclosure.

FIG. 11A is a schematic top view of a partition of a display substrate according to at least one embodiment of the present disclosure.

FIG. 11B is a schematic diagram of the display substrate after a ninth insulation layer is formed in FIG. 11A.

FIG. 11C is a schematic diagram of the display substrate after an anode layer is formed in FIG. 11A.

FIG. 12 is a cross-sectional view of a partition taken along a P-P′ direction in FIG. 11A.

FIG. 13 is another cross-sectional view of a partition of a second display region according to at least one embodiment of the present disclosure.

FIG. 14A is a top view of a partition of a display substrate according to at least one embodiment of the present disclosure.

FIG. 14B is a schematic diagram of the display substrate after a ninth insulation layer is formed in FIG. 14A.

FIG. 14C is a schematic diagram of the display substrate after an anode layer is formed in FIG. 14A.

FIG. 15 is a schematic diagram of a display apparatus according to at least one embodiment of the present disclosure.

### DETAILED DESCRIPTION

The embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main portion and a secondary portion connected with the main portion, the main portion is a line, a line segment, or a strip-shaped body, the main portion extends along the B direction, and a length of the main portion extending along the B direction is greater than a length of the secondary portion extending along another direction. In following description, “A extends along a B direction” means “a main portion of A extends along a B direction”.

During processing of a pixel circuit of a display substrate, static electricity is generated, which is easy to accumulate in a long wire, resulting in a risk of Electro-Static Discharge (ESD) in a display region. Due to a limited space of the display substrate using the under display camera technology, there is no effective electrostatic lead-out circuit in the display region, which leads to a severe ESD problem in a production process of the pixel circuit of the display substrate using the under display camera technology, thereby bringing a large yield loss.

A display substrate is provided in an embodiment of the present disclosure, which includes a base substrate and a circuit structure layer located on the base substrate. The base substrate includes a display region and a peripheral region located at a periphery of the display region. The display region includes a first display region and a second display region, and the first display region at least partially surrounds the second display region. The circuit structure layer includes a plurality of pixel circuits, a plurality of initial signal lines, and at least one electrostatic conductive line. A plurality of initial signal lines are electrically connected with a plurality of pixel circuits and extend along a first direction, and at least one electrostatic conductive line extends along a second direction. A plurality of pixel circuits are located in the first display region, and a plurality of initial signal lines are located at least in the first display region. At least one electrostatic conductive line is electrically connected with at least two initial signal lines.

According to the display substrate in the embodiment, at least two initial signal lines are connected with the electrostatic conductive line, a static electricity consumption circuit can be formed by the initial signal lines and the electrostatic conductive line, consuming static electricity generated in the manufacturing process, thereby effectively reducing the ESD risk in the display region.

In some exemplary implementations, the at least one electrostatic conductive line may be located in the peripheral region. In this example, the electrostatic conductive line is disposed in the peripheral region, so that a wiring space of the display region may be not occupied by the electrostatic conductive line. However, the embodiment is not limited thereto. In some other examples, at least one electrostatic conductive line may be located in the first display region, for example, may be close to the peripheral region.

In some exemplary implementations, the display substrate may further include a light emitting structure layer located on a side of the circuit structure layer away from the base substrate. The light emitting structure layer may include a plurality of first light emitting elements located in the first display region, and a plurality of second light emitting elements located in the second display region. The plurality of pixel circuits include a plurality of first pixel circuits, and a plurality of second pixel circuits. At least one first pixel circuit in the plurality of first pixel circuits is electrically connected with at least one first light emitting element in the plurality of first light emitting elements, and at least one second pixel circuit in the plurality of second pixel circuits is electrically connected with at least one second light emitting element in the plurality of second light emitting elements.

In some exemplary implementations, a plurality of pixel circuits arranged along the first direction are one row of pixel circuits. The circuit structure layer may further include a plurality of first signal lines that may extend along the first direction and be electrically connected with a row of pixel circuits. An orthographic projection of the at least one electrostatic conductive line on the base substrate may be overlapped with orthographic projections of the plurality of first signal lines on the base substrate. For example, the plurality of first signal lines may extend from the first display region to the peripheral region, and are overlapped with an electrostatic conductive line in the peripheral region. For example, an orthographic projection of the at least one electrostatic conductive line on the base substrate may be overlapped with orthographic projections of two or three first signal lines on the base substrate. However, the embodiment is not limited thereto.

In some exemplary implementations, the at least one electrostatic conductive line may be located on a side of the plurality of first signal lines close to the base substrate, and the plurality of first signal lines may be located on a side of the plurality of initial signal lines close to the base substrate. In some examples, in a direction perpendicular to the display substrate, a circuit structure layer of the first display region may at least comprise a semiconductor layer, a first conductive layer, and a second conductive layer sequentially disposed on the base substrate. The semiconductor layer may include active layers of transistors of the plurality of pixel circuits; the first conductive layer may include gates of the transistors of the plurality of pixel circuits, and first capacitor plates of storage capacitors of the plurality of pixel circuits; and the second conductive layer may include second capacitor plates of the storage capacitors of the plurality of pixel circuits. At least one electrostatic conductive line may be located on the semiconductor layer, at least two first signal lines may be located on the first conductive layer, and a plurality of initial signal lines may be located on the second conductive layer.

In some exemplary implementations, the plurality of initial signal lines may include at least one first initial signal line, and at least one second initial signal line. The at least one electrostatic conductive line may include at least one first electrostatic conductive line. A first initial signal line and a second initial signal line that are electrically connected with pixel circuits in a same row may be electrically connected with a same first electrostatic conductive line. In some examples, an orthographic projection of the first electrostatic conductive line on the base substrate is overlapped with orthographic projections of two first signal lines on the base substrate, the two first signal lines may include a first scan line and a light emitting control line that are electrically connected with pixel circuits in a same row. In this example, the first electrostatic conductive line may be electrically connected with adjacent first and second initial signal lines, and overlapped with two first signal lines to form two electrostatic conductive control transistors. In a manufacturing process, when static electricity exists in the two first signal lines, two electrostatic conduction control transistors are turned on to make the first initial signal line and the second initial signal line be conductive, to form a static electricity consumption circuit, so that static electricity is consumed in the circuit, avoiding burning the transistors.

In some exemplary implementations, the plurality of initial signal lines may include a plurality of first initial signal lines and a plurality of second initial signal lines. The at least one electrostatic conductive line may include a second electrostatic conductive line and a third electrostatic conductive line. The second electrostatic conductive line may be electrically connected with the plurality of first initial signal lines, and the third electrostatic conductive line may be electrically connected with the plurality of second initial signal lines. In some examples, an orthographic projection of a second electrostatic conductive line connected between two adjacent first initial signal lines on the base substrate is overlapped with orthographic projections of three first signal lines on the base substrate; and an orthographic projection of a third electrostatic conductive line connected between two adjacent second initial signal lines on the base substrate is overlapped with orthographic projections of three first signal lines on the base substrate. In this example, initial signal lines transmitting a same initial signal may be electrically connected with a same electrostatic conductive line. For example, the electrostatic conductive line may be electrically connected with adjacent initial signal lines that transmit the same signal, and is overlapped with three first signal lines to form three electrostatic conductive control transistors. In a manufacturing process, when static electricity exists in the three first signal lines, all of three electrostatic conduction control transistors are turned on to make adjacent initial signal lines transmitting a same signal be conductive, so as to form an static electricity consumption circuit, so that static electricity is consumed in the loop, avoiding burning the transistors.

In some exemplary implementations, at least one electrostatic conductive line may be located on a side of the plurality of initial signal lines away from the base substrate. In this example, the electrostatic conductive line may be electrically connected with a plurality of initial signal lines, and a loop is formed at tips of the initial signal lines to consume static electricity, avoiding static electricity accumulation.

Solutions of the embodiments will be described below through some examples.

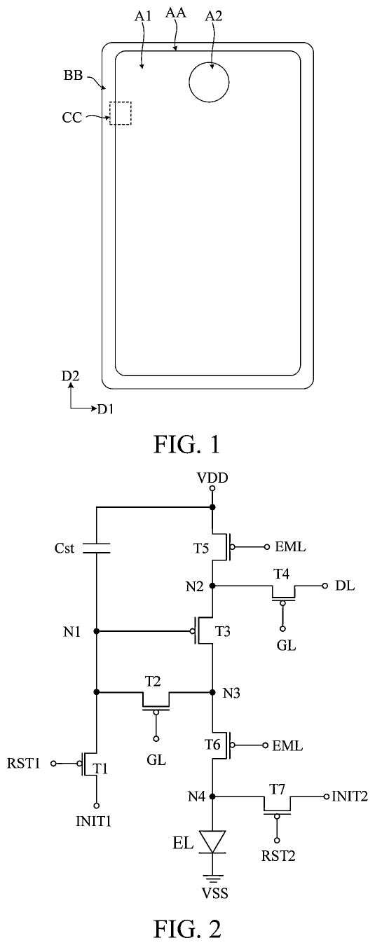

FIG. 1 is a schematic diagram of a display substrate according to at least one embodiment of the present disclosure. In some examples, as shown in FIG. 1, the display substrate may include a display region AA, and a peripheral region BB surrounding a periphery of the display region AA. The display region AA of the display substrate may include a first display region A1 and a second display region A2. The first display region A1 at least partially surrounds the second display region A2. In this example, the first display region A1 may surround the second display region A2.

In some examples, as shown in FIG. 1, the second display region A2 may be a light-transmitting display region which may also be referred to as a Full Display with Camera (FDC) region. The first display region A1 may be a normal display region. For example, an orthographic projection of a photosensitive sensor (such as a camera or other hardware) on the display substrate may be located in the second display region A2 of the display substrate. In some examples, as shown in FIG. 1, the second display region A2 may be circular, and a dimension of an orthographic projection of the photosensitive sensor on the display substrate may be less than or equal to a dimension of the second display region A2. However, the embodiment is not limited thereto. In some other examples, the second display region A2 may be rectangular, and a dimension of an orthographic projection of the photosensitive sensor on the display substrate may be less than or equal to a dimension of an inscribed circle of the second display region A2.

In some examples, as shown in FIG. 1, the second display region A2 may be located at a top center position of the display region AA. The first display region A1 may surround the second display region A2. However, the embodiment is not limited thereto. For example, the second display region A2 may be located in another position, such as an upper left corner or an upper right corner, of the display region AA. For example, the first display region A1 may surround at least one side of the second display region A2.

In some examples, as shown in FIG. 1, the display region AA may be in a shape of a rectangle, e.g., a rounded rectangle. The second display region A2 may be circular or elliptical. However, the embodiment is not limited thereto. For example, the second display region A2 may be rectangular, semi-circular, pentagonal, or in another shape.

In some examples, the display region AA may be provided with a plurality of sub-pixels. At least one sub-pixel may include a pixel circuit and a light emitting element. The pixel circuit is configured to drive a connected light emitting element. For example, the pixel circuit is configured to provide a drive current to drive the light emitting element to emit light. The pixel circuit may include a plurality of transistors and at least one capacitor. For example, the pixel circuit may be of a 3T1C (i.e., three transistors and one capacitor) structure, a 7T1C (i.e., seven transistors and one capacitor) structure, a 5T1C (i.e., five transistors and one capacitor) structure, an 8T1C (eight transistors and one capacitor) structure, or an 8T2C (eight transistors and two capacitors) structure, or the like.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under driving of a pixel circuit corresponding to the light emitting element. A color of light emitted by the light emitting element may be determined as required. In some examples, the light emitting element may include an anode, a cathode, and an organic light emitting layer located between the anode and the cathode. The anode of the light emitting element may be electrically connected with a corresponding pixel circuit. However, the embodiment is not limited thereto.

In some examples, one pixel unit in the display region may include three sub-pixels, which may be a red sub-pixel, a green sub-pixel, and a blue sub-pixel, respectively. However, the embodiment is not limited thereto. In some examples, one pixel unit may include four sub-pixels, which may be a red sub-pixel, a green sub-pixel, a blue sub-pixel, and a white sub-pixel, respectively.

In some examples, the light emitting element may be in a shape of a rectangle, a rhombus, a pentagon, or a hexagon. When one pixel unit includes three sub-pixels, light emitting elements of the three sub-pixels may be arranged in a manner of standing side by side horizontally, in a manner of standing side by side vertically, or in a Chinese character “ [symbol] ” arrangement. When one pixel unit includes four sub-pixels, light emitting elements of the four sub-pixels may be arranged in a manner of standing side by side horizontally, in a manner of standing side by side vertically, or in a square arrangement. However, the embodiment is not limited thereto.

FIG. 2 is an equivalent circuit diagram of a pixel circuit according to at least one embodiment of the present disclosure. The pixel circuit of this exemplary embodiment is described by taking a 7T1C structure as an example. However, the embodiment is not limited thereto.

In some exemplary implementations, as shown in FIG. 2, the pixel circuit according to this example may include seven transistors (i.e., a first transistor T1 to a seventh transistor T7) and one storage capacitor Cst. The light emitting element EL may include an anode, a cathode and an organic light emitting layer arranged between the anode and the cathode.

In some exemplary embodiments, the seven transistors of the pixel circuit may be P-type transistors, or may be N-type transistors. Same type of transistors in the pixel circuit may simplify a process flow, reduce a process difficulty of the display substrate, and improve a yield of a product. In some possible implementations, the seven transistors in the pixel circuit may include a P-type transistor and an N-type transistor.

In some exemplary implementations, the seven transistors in the pixel circuit may be low temperature poly-silicon thin film transistors, or may be oxide thin film transistors, or may be low temperature poly-silicon thin film transistors and oxide thin film transistors. An active layer of the low temperature poly-crystalline silicon thin film transistor is made of Low Temperature Poly-crystalline Silicon (LTPS), and an active layer of the oxide thin film transistor is made of an oxide semiconductor (Oxide). The low temperature poly-crystalline silicon thin film transistor has advantages, such as a high mobility, and fast charging, etc., while the oxide thin film transistor has advantages, such as a low leakage current, etc. The low temperature poly-silicon thin film transistor and the oxide thin film transistor are integrated on one display substrate to form a low temperature poly-crystalline oxide (LTPS+Oxide) display substrate, and advantages of both the low temperature poly-crystalline silicon thin film transistor and the oxide thin film transistor can be utilized, which can achieve low frequency drive, reduce power consumption, and improve display quality.

In some exemplary embodiments, as shown in FIG. 2, the display substrate may include a first scan line GL, a data line DL, a first power supply line VDD, a second power supply line VSS, a light emitting control line EML, a first initial signal line INIT1, a second initial signal line INIT2, a second scan line RST1, and a third scan line RST2. In some examples, the first power supply line VDD may be configured to provide a constant first voltage signal to the pixel circuit, and the second power supply line VSS may be configured to provide a constant second voltage signal to the pixel circuit, wherein the first voltage signal may be greater than the second voltage signal. The first scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the second scan line RST1 may be configured to provide a first reset control signal RESET1 to the pixel circuit, and the third scan line RST2 may be configured to provide a second reset control signal RESET2 to the pixel circuit. In some examples, a second scan line RST1 electrically connected with a pixel circuit in an n-th row may be electrically connected with a first scan line GL of a pixel circuit in an (n−1)-th row, so as to be inputted with a scan signal SCAN(n−1). That is, a first reset control signal RESET1(n) is the same as the scan signal SCAN(n−1). A third scan line RST2 of the pixel circuit in the n-th row may be electrically connected with a first scan line GL of the pixel circuit in the n-th row, so as to be inputted with a scan signal SCAN(n). That is, a second reset control signal RESET2(n) may be the same as the scan signal SCAN(n). Herein, n is an integer greater than 0. Thus, signal lines of the display substrate can be reduced, thereby achieving a narrow bezel design for the display substrate. However, the embodiment is not limited thereto.

In some exemplary implementations, the first initial signal line INIT1 may be configured to provide a first initial signal to the pixel circuit, the second initial signal line INIT2 may be configured to provide a second initial signal to the pixel circuit. For example, the first initial signal may be different from the second initial signal. The first initial signal and the second initial signal may be constant voltage signals, and their magnitudes may be between a first voltage signal and a second voltage signal, but are not limited thereto. In some other examples, the first initial signal and the second initial signal may be the same, and only the first initial signal line may be disposed to provide the first initial signal.

In some exemplary implementations, as shown in FIG. 2, a gate of the third transistor T3 is electrically connected with a first node N1, a first electrode of the third transistor T3 is electrically connected with a second node N2, and a second electrode of the third transistor T3 is electrically connected with a third node N3. The third transistor T3 may be referred to as a drive transistor. A gate of the fourth transistor T4 is electrically connected with the first scan line GL, a first electrode of the fourth transistor T4 is electrically connected with the data line DL, and a second electrode of the fourth transistor T4 is electrically connected with the first electrode of the third transistor T3. The fourth transistor T4 may be referred to as a data writing transistor. A gate of the second transistor T2 is electrically connected with the first scan line GL, a first electrode of the second transistor T2 is electrically connected with the gate of the third transistor T3, and a second electrode of the second transistor T2 is electrically connected with the second electrode of the third transistor T3. The second transistor T2 may also be referred to as a threshold compensation transistor. A gate of the fifth transistor T5 is electrically connected with the light emitting control line EML, a first electrode of the fifth transistor T5 is electrically connected with the first power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may also be referred to as light emitting control transistors. The first transistor T1 is electrically connected with the gate of the third transistor T3, and configured to reset the gate of the third transistor T3. The seventh transistor T7 is electrically connected with the anode of the light emitting element EL, and configured to reset the anode of the light emitting element EL. A gate of the first transistor T1 is electrically connected with the second scan line RST1, a first electrode of the first transistor T1 is electrically connected with the first initial signal line INIT1, and a second electrode of the first transistor T1 is electrically connected with the gate of the third transistor T3. A gate of the seventh transistor T7 is connected with the third scan line RST2, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first capacitor plate of the storage capacitor Cst is electrically connected with the gate of the third transistor T3, and a second capacitor plate of the storage capacitor Cst is electrically connected with the first power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, and the fourth node N4 is a connection point for the sixth transistor T6, the seventh transistor T7, and the light emitting element EL.

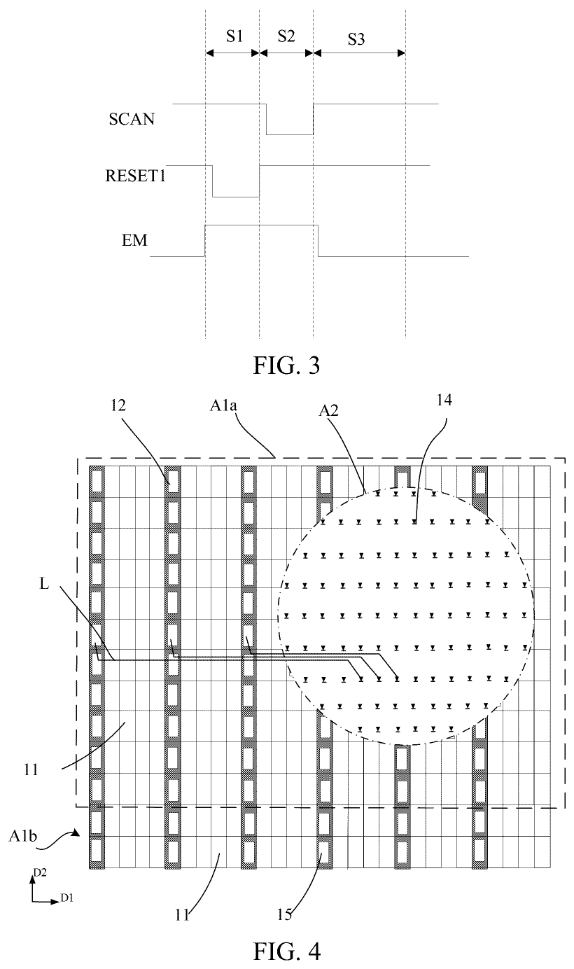

FIG. 3 is a working timing diagram of the pixel circuit shown in FIG. 2. Referring to FIG. 3, the description is made by taking a case in which all of a plurality of transistors included in the pixel circuit shown in FIG. 2 are P-type transistors as an example. The second reset control signal provided by the third scan line RST2 may be the same as the scan signal provided by the first scan line GL.

In some exemplary implementations, during one frame of display period, an operating process of the pixel circuit may include a first stage S1, a second stage S2, and a third stage S3.

The first stage S1 is referred to as a reset stage. A first reset control signal RESET1 provided by the second reset control line RST1 is a low-level signal, so that the first transistor T1 is turned on, and a first initial signal provided by the first initial signal line INIT1 is provided to the first node N1 to initialize the first node N1 and clear an original data voltage in the storage capacitor Cst. A scan signal SCAN provided by the first scan line GL is a high-level signal and the light control signal EM provided by the light emitting control line EML is a high-level signal, so that the fourth transistor T4, the second transistor T2, the fifth transistor T5, the sixth transistor T6, and the seventh transistor T7 are turned off. In this stage, the light emitting element EL does not emit light.

A second stage S2 is referred to as a data writing stage or a threshold compensation stage. A scan signal SCAN provided by the first scan line GL is a low-level signal, both the first reset control signal RESET1 provided by the second scan line RST1 and a light emitting control signal EM provided by the light emitting control line EML are high-level signals, and the data line DL outputs a data signal. In this stage, the first capacitor plate of the storage capacitor Cst is at a low-level, so that the third transistor T3 is turned on. The scan signal SCAN is a low-level signal, so that the second transistor T2, the fourth transistor T4, and the seventh transistor T7 are turned on. The second transistor T2 and the fourth transistor T4 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage at the first capacitor plate (i.e., the first node N1) of the storage capacitor Cst is Vdata−|Vth|, wherein Vdata is the data voltage output by the data line DL, and Vth is the threshold voltage of the third transistor T3. The seventh transistor T7 is turned on, so that a second initial signal provided by the second initial signal line INIT2 is provided to the anode of the light emitting element EL to initialize (reset) the anode of the light emitting element EL and clear a voltage therein stored in advance, so as to complete initialization, thereby ensuring that the light emitting element EL does not emit light. The first reset control signal RESET1 provided by the second scan line RST1 is a high-level signal, so that the first transistor T1 is turned off. The light emitting control signal EM provided by the light emitting control signal line EML is a high-level signal, so that the fifth transistor T5 and the sixth transistor T6 are turned off.

The third stage S3 is referred to as a light emitting stage. The light emitting control signal EM provided by the light emitting control line EML is a low-level signal, and the scan signal SCAN provided by the first scan line GL and the first reset control signal RESET1 provided by the second scan line RST1 are high-level signals. The light emitting control signal EM provided by the light emitting control line EML is a low-level signal, so that the fifth transistor T5 and the sixth transistor T6 are turned on, and the first voltage signal output by the first power supply line VDD provides a drive voltage to the anode of the light emitting element EL through the turned-on fifth transistor T5, the turned-on third transistor T3 and the turned-on sixth transistor T6 to drive the light emitting element EL to emit light.

In a driving process of the pixel circuit, a drive current flowing through the third transistor T3 is determined by a voltage difference between the gate and the first electrode of the third transistor T3. Since the voltage at the first node N1 is Vdata−|Vth|, the drive current of the third transistor T3 is as follows.

$$I = K \times [ {( Vgs - Vth )}^{2} = K \times {[ ( Vdd - V data + \vert Vth \vert ) - Vth ]}^{2} = K \times {[ Vdd - V data ]}^{2}$$

Herein I is the drive current flowing through the third transistor T3 (i.e., a drive current for driving the light emitting element EL), K is a constant, Vgs is the voltage difference between the gate and the first electrode of the third transistor T3, Vth is the threshold voltage of the third transistor T3, Vdata is the data voltage output by the data line DL, and Vdd is the first voltage signal output by the first power supply line VDD.

It may be seen from the abovementioned formula that a current flowing through the light emitting element EL is independent of the threshold voltage of the third transistor T3. Therefore, the pixel circuit in this embodiment may compensate the threshold voltage of the third transistor T3 well.

FIG. 4 is a schematic diagram of a partition of a display substrate according to at least one embodiment of the present disclosure. In some examples, as shown in FIG. 4, the first display region A1 of the display substrate may include a transition region A1a and a non-transition region A1b. The transition region A1a may be located on at least one side outside the second display region A2 (for example, on one side; for another example, surrounding the second display region A2 (i.e., including upper and lower sides and left and right sides)).

In some examples, the second display region A2 may include a plurality of second light emitting elements 14 arranged in an array. The transition region A1a may include a plurality of first pixel circuits 11 and a plurality of second pixel circuits 12 arranged in an array, and may further include a plurality of first light emitting elements. At least one first pixel circuit 11 within the transition region A1a may be electrically connected with at least one first light emitting element, and configured to drive the first light emitting element to emit light. An orthographic projection of the first light emitting element on the base substrate may be overlapped, at least partially, with an orthographic projection of the electrically connected first pixel circuit 11 on the base substrate. At least one second pixel circuit 12 may be electrically connected with at least one second light emitting element 14 disposed within the second display region A2 through a conductive line L (e.g., a transparent conductive line), and configured to drive the second light emitting element 14 to emit light. For example, one end of the conductive line L may be electrically connected with the second pixel circuit 12, and another end of the conductive line L may be electrically connected with the second light emitting element 14, and the conductive line L may extend from the transition region A1a to the second display region A2. An orthographic projection of the second pixel circuit 12 on the base substrate may not be overlapped with an orthographic projection of the electrically connected second light emitting element 14 on the base substrate. In this example, each second light emitting element 14 in the second display region A2 may be electrically connected to a second pixel circuit 12 in the transition region A1a through at least one conductive line L. By disposing the second pixel circuit 12 for driving the second light emitting element 14 in the transition region A1a, light shaded by the pixel circuit can be reduced, thereby increasing a light transmittance of the second display region A2.

In some examples, the conductive line L may be made of a transparent conductive material, for example, may be made of a conductive oxide material, such as Indium Tin Oxide (ITO). However, the embodiment is not limited thereto.

In some examples, as shown in FIG. 4, the non-transition region A1b may include a plurality of first pixel circuits 11 and a plurality of dummy pixel circuits 15 arranged in an array, and may further include a plurality of first light emitting elements. At least one first pixel circuit 11 within the non-transition region A1b may be electrically connected with at least one first light emitting element, and an orthographic projection of the first light emitting element on the base substrate may be overlapped, at least partially with, an orthographic projection of the electrically connected first pixel circuit 11 on the base substrate.

In some examples, as shown in FIG. 4, the transition region A1a and the non-transition region A1b may further include a plurality of dummy pixel circuits 15. Disposing the dummy pixel circuits may be beneficial to improving uniformity of components of a plurality of films in an etching process. For example, a structure of the dummy pixel circuit may be substantially the same as structures of a first pixel circuit and a second pixel circuit in a row or a column where the dummy pixel circuit is located, except that the dummy pixel circuit is not electrically connected with any light emitting element.

In some examples, since the first display region A1 is provided with not only a first pixel circuit electrically connected with a first light emitting element, but also a second pixel circuit electrically connected with a second light emitting element, a quantity of pixel circuits of the first display region A1 may be greater than a quantity of first light emitting elements. In some examples, as shown in FIG. 4, a region where newly added pixel circuits (including a second pixel circuit and a dummy pixel circuit) are disposed may be obtained by reducing a dimension of a first pixel circuit 11 in a first direction D1. For example, a dimension of a pixel circuit in the first direction D1 may be smaller than a dimension of a first light emitting element in the first direction D1. In this example, as shown in FIG. 4, original pixel circuits of every a columns may be compressed along the first direction D1, thereby obtaining an arrangement space for one newly added column of pixel circuits, and space occupied by the a columns of pixel circuits before compression may be the same as space occupied by the a+1 columns of pixel circuits after compression. Herein, a may be an integer greater than 1. In some examples, a may be equal to 4. However, the embodiment is not limited thereto. For example, a may be equal to 2 or 3.

In some other examples, original pixel circuits in b rows may be compressed along a second direction D2, thereby obtaining an arrangement space for one newly added row of pixel circuits, and space occupied by b rows of pixel circuits before compression and space occupied by b+1 rows of pixel circuits after compression are the same. Herein, b may be an integer greater than 1. Or, a region in which newly added pixel circuits are disposed may be obtained by reducing dimensions of a first pixel circuit in the first direction D1 and the second direction D2.

In an embodiment of the present disclosure, a row of light emitting elements may refer to that all pixel circuits connected to the row of light emitting elements are connected to a same gate line (for example, a scan line); And one row of pixel circuits may refer to a plurality of pixel circuits sequentially arranged along the first direction, and all the pixel circuits in the one row may be connected to a same gate line. However, the embodiment is not limited thereto.

In some examples, as shown in FIG. 1, the peripheral region BB may include a left bezel region and a right bezel region located on opposite sides of the display region AA along a first direction D1, and an upper bezel region and a lower bezel region located on opposite sides of the display region AA along a second direction D2. Structures of the left bezel region and the right bezel region may be substantially the same, and the structure of the left bezel region is taken as an example for description in following examples.

In some examples, the lower bezel region may include a fan-out region, a bending region, a drive chip region, and a bonding pin region that are sequentially disposed along a direction away from the display region AA. The fan-out region is connected to the display region AA, and may include a plurality of data lead-out lines configured to connect data lines of the display region in a fan-out routing manner. The bending region may be connected to the fan-out region, may include a composite insulation layer provided with a groove, and is configured to enable the drive chip region and the bonding pin region to be bent to a back surface of the display region AA. The drive chip region may be provided with an Integrated Circuit (IC) that may be configured to connect with a plurality of data fan-out lines. The bonding pin region may include a bonding pad that may be configured to bond and connect with an external Flexible Printed Circuit (FPC).

In some examples, the left bezel region may include a circuit region, a power supply line region, a crack dam region, and a cutting region which are sequentially disposed along the direction away from the display region AA. The circuit region may be connected to the display region AA, and may include, at least, a gate drive circuit, a first initial peripheral trace, and a second initial peripheral trace. The first initial peripheral traces may be configured to transmit a first initial signal, and the second initial peripheral traces may be configured to transmit a second initial signal. The gate drive circuit may be located on a side of the second initial peripheral traces away from the display region AA, and the first initial peripheral traces may be located on a side of the second initial peripheral traces close to the display region AA. The first initial peripheral traces and the second initial peripheral traces may extend from the left bezel region to the lower bezel region, for example, may be electrically connected with the bonding pads of the bonding pin region to receive the first initial signal and the second initial signal, respectively. The gate drive circuit may be electrically connected with a scan line and a light emitting control line with which a pixel circuit in the display region AA is connected. The power supply line region may be connected to the circuit region, and may at least include a bezel power supply lead line, the bezel power supply lead line may extend along a direction parallel to an edge of the display region, and be electrically connected with a cathode of a light emitting element in the display region AA. The crack dam region may be connected to the power supply line region, and may at least include a plurality of cracks disposed on the composite insulation layer. The cutting region may be connected to the crack dam region, and may at least include a cutting groove disposed on the composite insulation layer, and the cutting groove is configured for cutting along the cutting groove by a cutting equipment after all film layers of the display substrate are manufactured.

In some examples, both the first initial peripheral trace and the second initial peripheral trace may be double-layered traces, wherein the first initial peripheral trace may include a first initial sub-trace and a third initial sub-trace stacked and electrically connected to each other, and the second initial peripheral trace may include a second initial sub-trace and a fourth initial sub-trace stacked and electrically connected to each other. However, the embodiment is not limited thereto. For example, the first initial peripheral trace and the second initial peripheral trace may be single-layered traces.

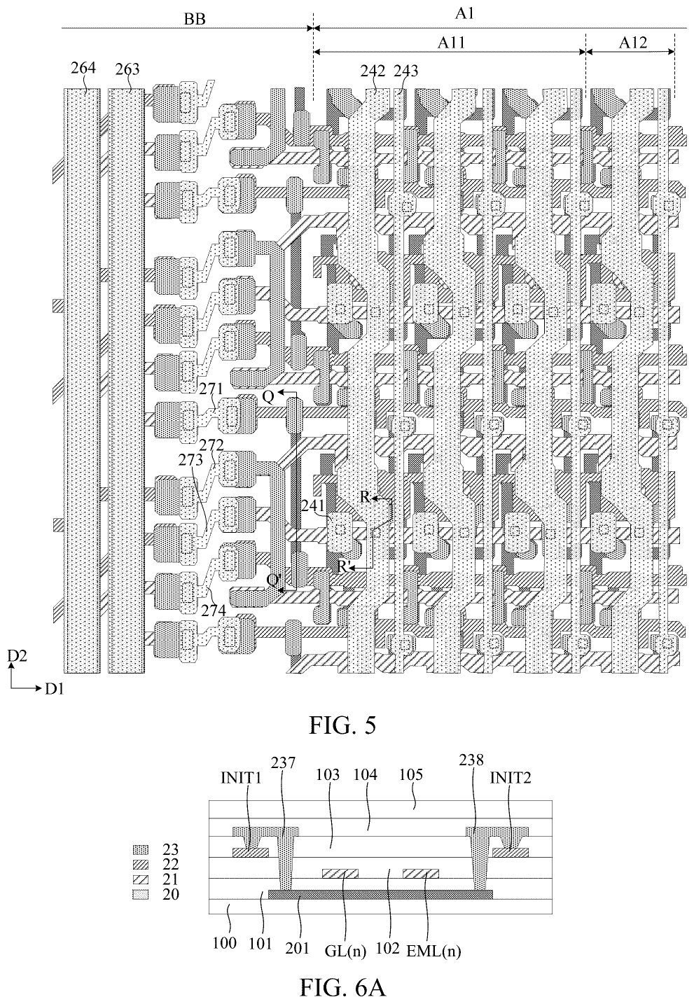

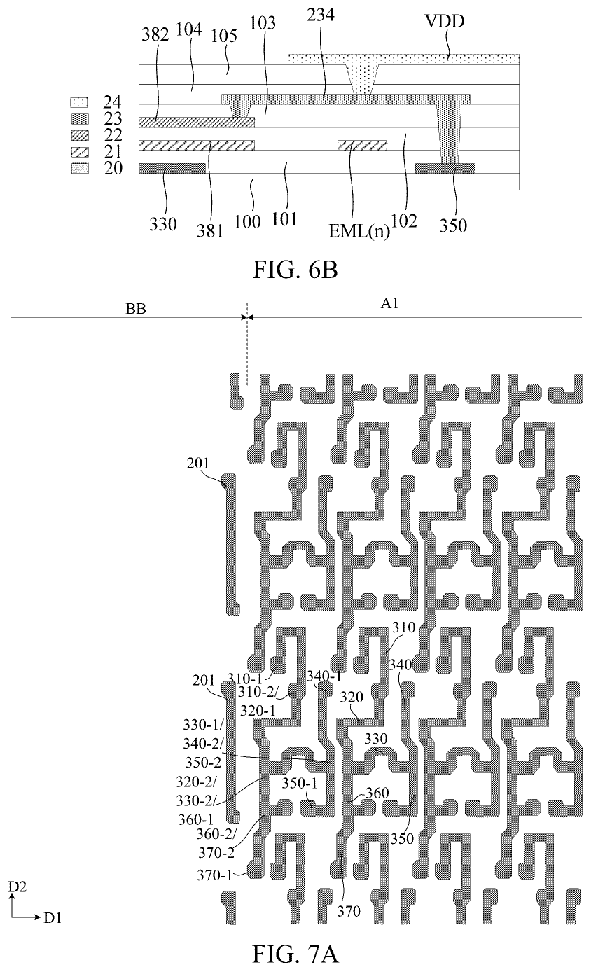

FIG. 5 is an enlarged schematic diagram of a partition of a circuit structure layer of the region CC in FIG. 1. FIG. 6A is a cross-sectional view of a partition taken along a Q-Q′ direction in FIG. 5. FIG. 6B is a cross-sectional view of a partition taken along an R-R′ direction in FIG. 5.

In some examples, as shown in FIG. 5, the first display region A1 may include a first circuit region A11 and a second circuit region A12 arranged in an interleaved mode the first direction D1. The first circuit region A11 may be provided with a plurality of columns of first pixel circuits (for example, three columns of first pixel circuits), and the second circuit region A12 may be provided with one column of dummy pixel circuits (for example, including a plurality of dummy pixel circuits) or may be provided with one column of pixel circuits including a dummy pixel circuit and a second pixel circuit. In the following examples, the first pixel circuit of the first circuit region A11 of the first display region A1 is taken as an example for illustration and description, and a film layer structure and a manufacturing process of a gate drive circuit of the peripheral region are omitted in the following examples.

In some examples, as shown in FIGS. 5, 6A and 6B, in a direction perpendicular to the display substrate, a circuit structure layer of the display substrate of the first display region A1 may include a semiconductor layer 20, a first conductive layer 21, a second conductive layer 22, a third conductive layer 23, and a fourth conductive layer 24 that are sequentially disposed on a base substrate 100. A first insulation layer 101 may be disposed between the semiconductor layer 20 and the first conductive layer 21, a second insulation layer 102 may be disposed between the first conductive layer 21 and the second conductive layer 22, a third insulation layer 103 may be disposed between the second conductive layer 22 and the third conductive layer 23, and a fourth insulation layer 104 and a fifth insulation layer 105 may be disposed between the third conductive layer 23 and the fourth conductive layer 24. In some examples, all of the first insulation layer 101 to the fourth insulation layer 104 may be inorganic insulation layers, and the fifth insulation layer 105 may be an organic insulation layer. The first conductive layer 21 may also be referred to as a first gate metal layer, the second conductive layer 22 may also be referred to as a second gate metal layer, the third conductive layer 23 may also be referred to as a first source-drain metal layer, and the fourth conductive layer 24 may also be referred to as a second source-drain metal layer. However, the embodiment is not limited thereto. In some other examples, only the fifth insulation layer may be disposed between the third conductive layer 23 and the fourth conductive layer 24.

A manufacturing process for a display substrate will be described below by way of example, with reference to FIGS. 5 to 7G. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

In some exemplary implementations, a manufacturing process of the display substrate may include following operations.

(1) A base substrate is provided. In some examples, the base substrate 100 may be a rigid substrate, or may be a flexible substrate. For example, the rigid substrate may be made of, but not limited to, one or more of glass and quartz. The flexible substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base substrate may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed, and a material of the first inorganic material layer and the second inorganic material layer may be silicon nitride (SiNx) or silicon oxide (SiOx), etc., which are used to improve resistance to water and oxygen of the base substrate.

(2) A semiconductor layer is formed. In some examples, a semiconductor thin film is deposited on the base substrate 100, and the semiconductor thin film is patterned through a patterning process to form semiconductor layers 20 in a first display region A1 and a peripheral region BB. In some examples, a material of the semiconductor layer 20 may be amorphous Silicon (a-Si), polycrystalline Silicon (p-Si), hexathiophene or polythiophene, or another material.

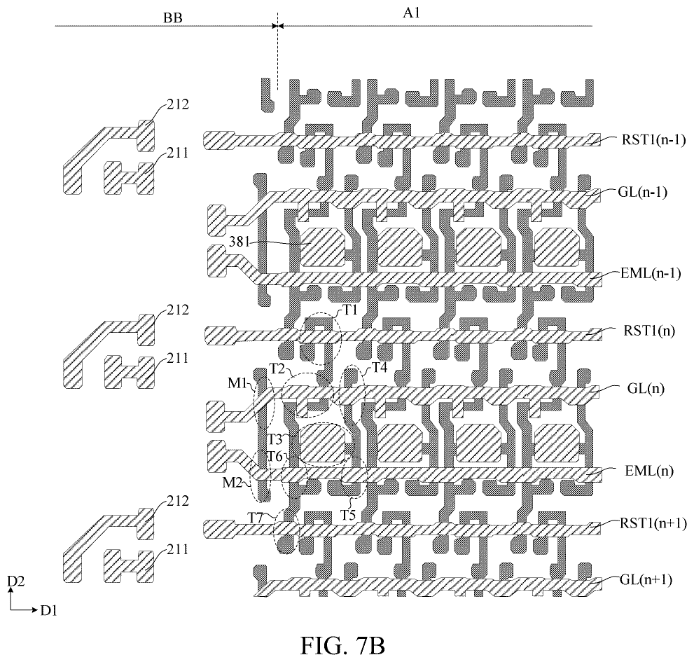

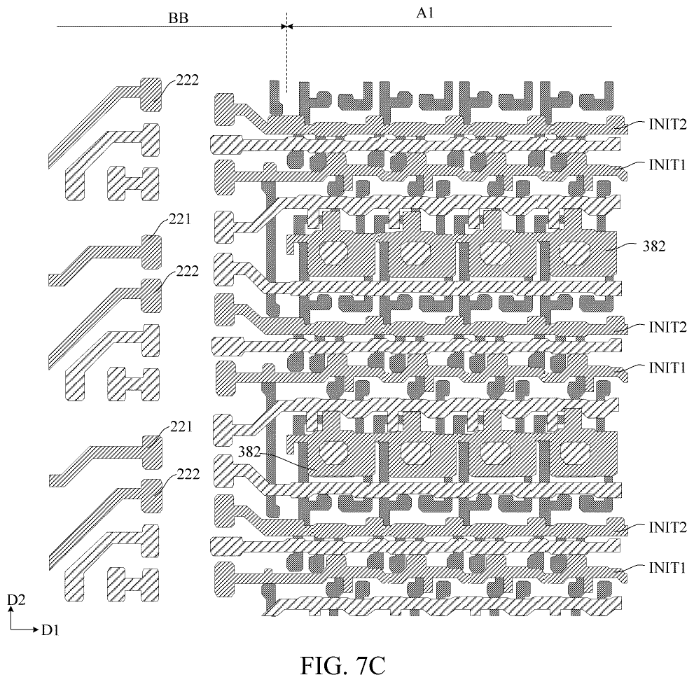

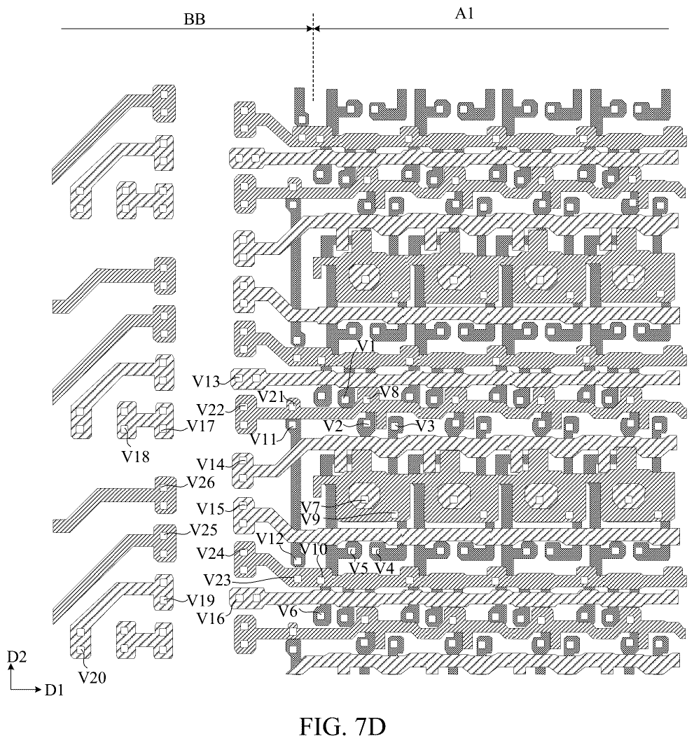

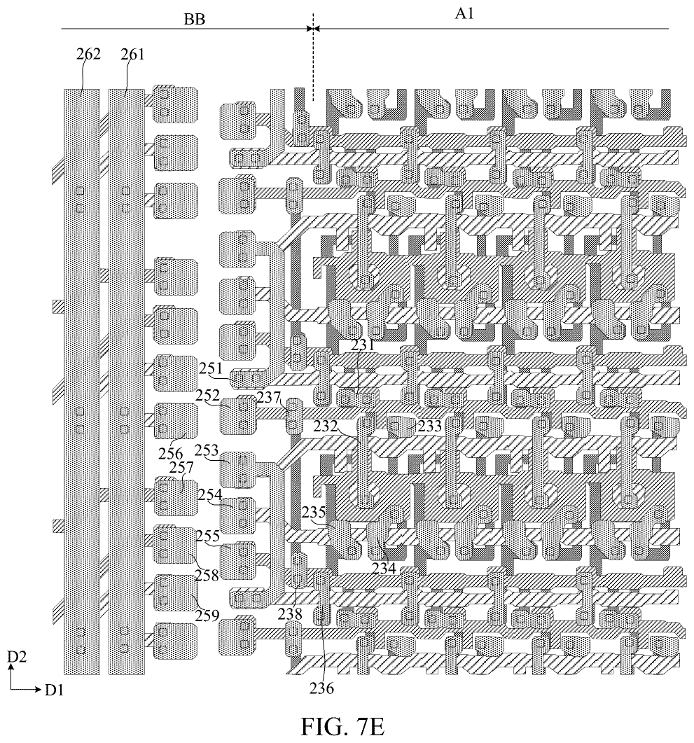

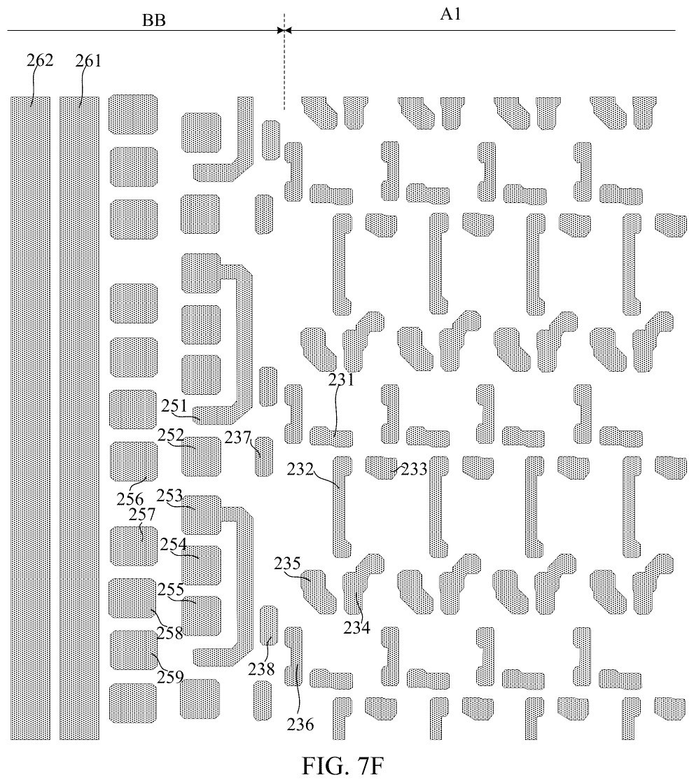

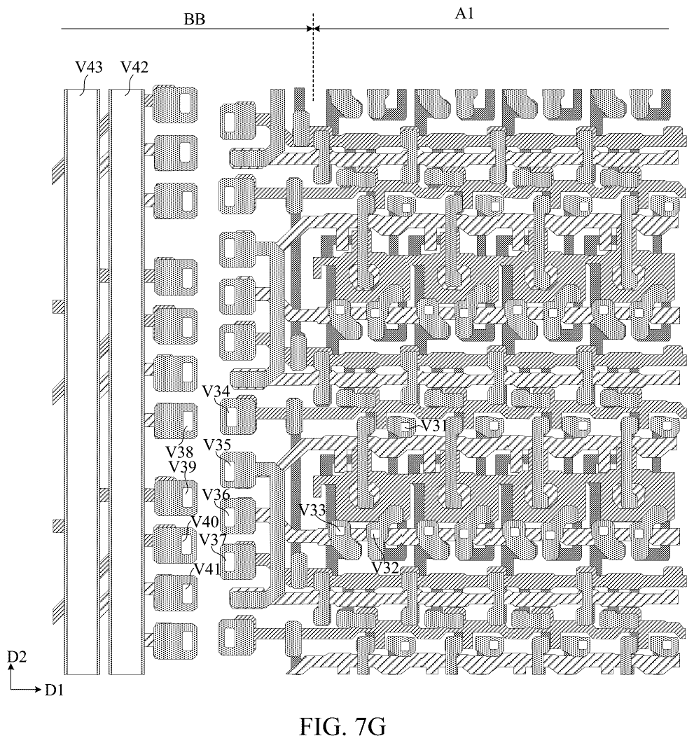

FIG. 7A is a schematic diagram of the circuit structure layer after a semiconductor layer is formed in FIG. 5. In some examples, as shown in FIG. 7A, the semiconductor layer 20 of the first circuit region A1 may at least include active layers of a plurality of transistors of a plurality of pixel circuits (including, for example, a first active layer 310 of a first transistor, a second active layer 320 of a second transistor, a third active layer 330 of a third transistor, a fourth active layer 340 of a fourth transistor, a fifth active layer 350 of a fifth transistor, a sixth active layer 360 of a sixth transistor, and a seventh active layer 370 of a seventh transistor, in a first pixel circuit). The first active layer 310 of the first transistor to the seventh active layer 370 of the seventh transistor in the first pixel circuit may be connected to each other to form an integral structure.

In some examples, as shown in FIG. 7A, the first active layer 310, the second active layer 320, and the fourth active layer 340 of the first pixel circuit may be located on one side of the third active layer 330 of the first pixel circuit in the second direction D2, and the fifth active layer 350, the sixth active layer 360, and the seventh active layer 370 of the first pixel circuit may be located on the other side of the third active layer 330 of the first pixel circuit in the second direction D2.

In some examples, as shown in FIG. 7A, the first active layer 310 of the first pixel circuit may be substantially inversed U-shaped, the second active layer 320, the fifth active layer 350, and the sixth active layer 360 may be substantially L-shaped, the third active layer 330 may be substantially n-shaped, and both the fourth active layer 340 and the seventh active layer 370 may be substantially I-shaped. However, the embodiment is not limited thereto.

In some examples, as shown in FIG. 7A, each of the active layer 310 of the first transistor 31 to the active layer 370 of the seventh transistor 37 of the first pixel circuit may include a first region, a second region, and a channel region disposed between the first and second regions. In some examples, a first region and a second region of an active layer may be interpreted as a source electrode or a drain electrode of a transistor. A part of active layers between transistors may be interpreted as wirings doped with impurities, and may be used for electrically connecting the transistors. The channel region may be not doped with impurities, and has characteristics of a semiconductor. The first region and the second region located on two sides of the channel region may be doped with impurities, so as to be conductive. The impurities may be changed according to a type of a transistor. However, the embodiment is not limited thereto.

In some examples, as shown in FIG. 7A, a first region 340-1 of the fourth active layer 340, a first region 350-1 of the fifth active layer 350, and a first region 370-1 of the seventh active layer 370 may be disposed separately. A second region 310-2 of the first active layer 310 may also serve as a first region 320-1 of the second active layer 320. A second region 320-2 of the second active layer 320 may also serve as a second region 330-2 of the third active layer 330 and a first region 360-1 of the sixth active layer 360. A first region 330-1 of the third active layer 330 may also serve as a second region 340-2 of the fourth active layer 340 and a second region 350-2 of the fifth active layer 350. A second region 360-2 of the sixth active layer 360 may also serve as a second region 370-2 of the seventh active layer 370.

In some examples, as shown in FIG. 7A, a semiconductor layer 20 of the peripheral region BB may at least include a plurality of first electrostatic conductive lines 201. The plurality of first electrostatic conductive lines 201 may extend along the second direction D2, and arranged in sequence along the second direction D2. The plurality of first electrostatic conductive lines 201 may be adjacent to the pixel circuits of the first display region A1 in the first direction D1.

(3) A first conductive layer is formed. In some examples, a first insulation thin film and a first conductive thin film are sequentially deposited on the base substrate 100 where the aforementioned structures are formed, and the first conductive thin film is patterned through a patterning process to form a first insulation layer 101 covering the semiconductor layer 20, and a first conductive layer 21 disposed on the first insulation layer 101.

FIG. 7B is a schematic diagram of the circuit structure layer after a first conductive layer is formed in FIG. 5. In some examples, as shown in FIG. 7B, the first conductive layer 21 of the first display region A1 may at least include gates of a plurality of transistors, and first capacitor plates of storage capacitors, of a plurality of pixel circuits (e.g. the gates of the plurality of transistors and first capacitor plates 381 of storage capacitors of the first pixel circuit), first scan lines (e.g. GL (n−1), GL (n), and GL (n+1)), light emitting control lines (e.g. EML (n−1) and EML (n)), and second scan lines (e.g. RST1 (n−1), RST1 (n), and RST1 (n+1)). where n is a positive integer. All of the first scan line, the second scan line, and the light emitting control line may be in a shape of a line in which the main portion extends along the first direction D1. Ends of the first scan line, the second scan line, and the light emitting control line may extend into the peripheral region BB. A first scan line with which a row of pixel circuits are electrically connected may be located between a second scan line and a light emitting control line with which the row of pixel circuits are electrically connected. In this example, a third scan line with which a row of pixel circuits are electrically connected is a second scan line with which a next row of pixel circuits are electrically connected.

In some examples, as shown in FIG. 7B, taking an n-th row of first pixel circuits as an example, an overlapping region of the second scan line RST1 (n) and a first active layer 310 of a first transistor T1 of the first pixel circuit in the n-th row may serve as a gate of the first transistor T1. An overlapping region of the first scan line GL (n) and a second active layer 320 of a second transistor T2 of the first pixel circuit in the n-th row may serve as a gate of the second transistor T2. An overlapping region of the first scan line GL (n) and a fourth active layer 340 of a fourth transistor T4 of the first pixel circuit in the n-th row may serve as a gate of the fourth transistor T4. An overlapping region of the light emitting control line EML (n) and a fifth active layer 350 of a fifth transistor T5 of the first pixel circuit in the n-th row may serve as a gate of the fifth transistor T5. An overlapping region of the light emitting control line EML (n) and a sixth active layer 360 of a sixth transistor T6 of the first pixel circuit in the n-th row may serve as a gate of the sixth transistor T6. An overlapping regions of the second scan line RST1 (n) and a seventh active layer 370 of a seventh transistors T7 of the first pixel circuit in the n-th row may serve as a gate of the seventh transistor T7.

In some examples, as shown in FIG. 7B, the first capacitor plate 381 of the storage capacitor of the first pixel circuit may be in a shape of a rectangle of which may be chamfered. An orthographic projection of the first capacitor plate 381 on the base substrate is overlapped with an orthographic projection of the third active layer 330 of the third transistor T3 of the first pixel circuit on the base substrate. The first capacitor plate 381 of the first pixel circuit may also serve as a plate of the storage capacitor, and the gate of the third transistor T3.

In some examples, after the first conductive layer 21 is formed, the semiconductor layer 20 may be made to be conductive by using the first conductive layer 21 as a shade. A semiconductor layer 20 in a region, which is shaded by the first conductive layer 21, may form a channel region of a transistor. A semiconductor layer 20 in a region, which is not shaded by the first conductive layer 21, may be made to be conductive. For example, all of the first regions and the second regions of the active layers of the seven transistors of the pixel circuit are made to be conductive.

In some examples, as shown in FIG. 7B, a first conductive layer 21 of the peripheral region BB may at least include a plurality of first initial adapter electrodes 211 and a plurality of second initial adapter electrodes 212. The first initial adapter electrodes 211 and the second initial adapter electrodes 212 may be arranged at intervals in the second direction D2, and may be aligned in the second direction D2.

In some examples, as shown in FIG. 7B, ends of the first scan line and the light emitting control line may extend to the peripheral region BB, and an orthographic projection of the first electrostatic conductive line 201 on the base substrate is overlapped with an orthographic projection of one first scan line and one light emitting control line on the base substrate. An overlapping region of the first electrostatic conductive line 201 with an orthographic projection of a first scan line (e.g. GL (n)) on the base substrate may serve as a channel region of a first electrostatic conduction control transistor M1, and an overlapping region of the first scan line with the first electrostatic conductive line 201 may serve as a gate of the first electrostatic conduction control transistor M1. An overlapping region of the first electrostatic conductive line 201 with an orthographic projection of a light emitting control line (e.g., EML (n)) on the base substrate may serve as a channel region of a second electrostatic conduction control transistor M2, and an overlapping region of the light emitting control line with an orthographic projection of the first electrostatic conductive line 201 on the base substrate may serve as a gate of the second electrostatic conduction control transistor M2. The first electrostatic conduction control transistor M1 may be adjacent to the second transistor T2 of the pixel circuit of the first display region A1 in the first direction D1, and the second electrostatic conduction control transistor M2 may be adjacent to the sixth transistor T6 of the pixel circuit of the first display region A1 in the first direction D1.

(4) A second conductive layer is formed. In some examples, a second insulation thin film and a second conductive thin film are deposited sequentially on the base substrate 100 on which the aforementioned structures are formed, and the second conductive thin film is patterned through a patterning process to form a second insulation layer 102, and a second conductive layer 22 disposed on the second insulation layer 102.

FIG. 7C is a schematic diagram of the circuit structure layer after a second conductive layer is formed in FIG. 5. In some examples, as shown in FIG. 7C, the second conductive layer 22 of the first display region A1 may at least include second capacitor plates of storage capacitors of a plurality of pixel circuits (e.g., a second capacitor plate 382 of the first pixel circuit), a plurality of first initial signal lines INIT1, and a plurality of second initial signal lines INIT2. A first initial signal line INIT1 and a second initial signal line INIT2 may be in a shape of a line in which a main portion extends along the first direction D1. An orthographic projection of the first initial signal line INIT1 on the base substrate may be located between an orthographic projection of a light emitting control line on the base substrate and an orthographic projection of a first scan line on the base substrate, and an orthographic projection of the second initial signal line INIT2 on the base substrate may be located between an orthographic projection of a light emitting control line one the base substrate and an orthographic projection of a first scan line on the base substrate. Ends of the first initial signal line INIT1 and the second initial signal line INIT2 may extend to the peripheral region BB. The orthographic projection of the second capacitor plate 382 of the first pixel circuit on the base substrate is overlapped with the orthographic projection of the first capacitor plate 381 on the base substrate. The second capacitor plate 382 may be provided with a hollow structure, and an orthographic projection of the hollow structure on the base substrate may be within a range of the orthographic projection of the first capacitor plate 381 on the base substrate. In some examples, in a row of pixel circuits, second capacitor plates of storage capacitors of adjacent pixel circuits may be electrically connected to each other, for example connected to each other to form an integral structure. A second capacitor plate of the integral structure may be reused as a power supply signal connection line, so as to ensure that a plurality of second capacitor plates in a row of pixel circuits are at a same potential, which is beneficial to improving uniformity of the display substrate, avoiding poor display of the display substrate, and ensuring a display effect of the display substrate.

In some examples, as shown in FIG. 7C, a second conductive layer 22 of the peripheral region BB may at least include a plurality of scan output lines 221 and a plurality of light emitting control output lines 222. A scan output line 221 may be configured to connect the first scan line to a scan signal output terminal of a corresponding gate drive circuit. A light emitting control output line 222 may be configured to connect a light emitting control line to a light emitting control signal output terminal of a corresponding gate drive circuit. A scan output line 221 and a light emitting control output line 222 are adjacent in the second direction D2. However, the embodiment is not limited thereto. For example, the scan output lines and the light emitting control output lines may be located in the first conductive layer.

In some examples, as shown in FIG. 7C, the ends of the first initial signal line INIT1 and the second initial signal line INT2 may extend to the peripheral region BB. The orthographic projections of the first initial signal line INIT1 and the second initial signal line INIT2 on the base substrate may be not overlapped with the orthographic projection of the first electrostatic conductive line 201 on the base substrate. Two ends of the first electrostatic conductive line 201 along the second direction D2 may be adjacent to the first initial signal line INIT1 and the second initial signal line INIT2, respectively.

(5) A third insulation layer is formed. In some examples, a third insulation thin film is deposited on the base substrate 100 where the aforementioned patterns are formed, and the third insulation thin film is patterned through a patterning process to form a third insulation layer 103. The third insulation layer 103 may be provided with a plurality of vias. For example, the plurality of vias may expose surfaces of the semiconductor layer 20, the first conductive layer 21, and the second conductive layer 22, respectively.

FIG. 7D is a schematic diagram of the circuit structure layer after a third insulation layer is formed in FIG. 5. In some examples, as shown in FIG. 7D, a third insulation layer 103 of the first display region A1 may be provided with a plurality of vias, which may include, for example, a first via V1 to a tenth via V10. Third insulation layers 103, second insulation layers 102, and first insulation layers 101 within the first via V1 to the sixth via V6 are removed to expose a surface of the semiconductor layer 20. A third insulation layer 103 and a second insulation layer 102 within the seventh via V7 are removed to expose a surface of the first conductive layer 21. Third insulation layers 103 within the eighth via V8 to the tenth via V10 are removed to expose a surface of the second conductive layer 22.

In some examples, as shown in FIG. 7D, a third insulation layer 103 of the peripheral region BB may be provided with a plurality of vias, which may include an eleventh via V11 to a twenty-sixth via V26, for example. Third insulation layers 103, second insulation layers 102, and first insulation layers 101 within the eleventh via V11 and the twelfth via V12 are removed to expose a surface of an electrostatic conductive line 201 located in the semiconductor layer 20. Third insulation layers 103 and second insulation layers 102 within the thirteenth via V13 to the sixteenth via V16 are removed to expose a surface of a second scan line located in the first conductive layer 21. A third insulation layer 103 and a second insulation layer 102 within the fourteenth via V14 are removed to expose a surface of a first scan line located in the first conductive layer 21. A third insulation layer 103 and a second insulation layer 102 within the fifteenth via V15 are removed to expose a surface of a light emitting control line located in the first conductive layer 21. Third insulation layers 103 and second insulation layers 102 within the seventeenth via V17 and the eighteenth via V18 are removed to expose a surface of a first initial adapter electrode 211 located in the first conductive layer 21. Third insulation layers 103 and second insulation layers 102 within the nineteenth via V19 and the twentieth via V20 are removed to expose a surface of a second initial adapter electrode 212 located in the first conductive layer 21. Third insulation layers 103 within the twenty-second via V22 and the twenty-first via V21 are removed to expose a surface of a first initial signal line INIT1 located in the second conductive layer 22. Third insulation layers 103 within the twenty-fourth via V24 and the twenty-third via V23 are removed to expose a surface of a second initial signal line INIT2 located in the second conductive layer 22. A third insulation layer 103 within the twenty-sixth via V26 is removed to expose a surface of a scan output line 221 located in the second conductive layer 22. A third insulation layer 103 in the twenty-fifth via V25 is removed to expose a surface of a light emitting control output line 222 located in the second conductive layer 22.

(6) A third conductive layer is formed. In some examples, a third conductive thin film is deposited on the base substrate 100 where the aforementioned patterns are formed, and the third conductive thin film is patterned through a patterning process to form a third conductive layer 23 on the third insulation layer 103.

FIG. 7E is a schematic diagram of the circuit structure layer after a third conductive layer is formed in FIG. 5. FIG. 7F is a schematic diagram of the third conductive layer in FIG. 7E. In some examples, as shown in FIGS. 7E and 7F, a third conductive layer 23 of the first display region A1 may include a plurality of pixel connection electrodes (including, for example, a first pixel connection electrode 231 to a sixth pixel connection electrode 236). As shown in FIGS. 7D to 7F, the first pixel connection electrode 231 may be electrically connected with a first region 310-1 of the first active layer 310 of the first transistor T1 of the first pixel circuit through the first via V1, and may also be electrically connected with a first initial signal line INIT1 through the eighth via V8. The second pixel connection electrode 232 may be electrically connected with a second region 310-2 of the first active layer 310 of the first transistor T1 of the first pixel circuit through the second via V2, and may also be electrically connected with a first capacitor plate 381 through the seventh via V7. The third pixel connection electrode 233 may be electrically connected with a first region 340-1 of the fourth active layer 340 of the fourth transistor T4 of the first pixel circuit through the third via V3. The fourth pixel connection electrode 234 may be electrically connected with a first region 350-1 of the fifth active layer 350 of the fifth transistor T5 of the first pixel circuit through the fourth via V4, and may also be electrically connected with a second capacitor plate 382 through the ninth via V9. The fifth pixel connection electrode 235 may be electrically connected with a second region 360-2 of the sixth active layer 360 of the sixth transistor T6 of the first pixel circuit through the fifth via V5. The sixth pixel connection electrode 236 may be electrically connected with a first region 370-1 of the seventh active layer 370 of the seventh transistor T7 of the first pixel circuit through the sixth via V6, and may also be electrically connected with the second initial signal line INIT2 through the tenth via V10.

In some examples, as shown in FIGS. 7E and 7F, a third conductive layer 23 of the peripheral region BB may include a first connection electrode 237, a second connection electrode 238, a plurality of output adapter electrodes (including, for example, a first output adapter electrode 251 to a ninth output adapter electrode 259), a first initial sub-trace 261 and a second initial sub-trace 262.

In some examples, as shown in FIGS. 7D to 7F, the first and second initial sub-traces 261 and 262 may extend along the second direction D2, and the first initial sub-trace 261 may be located on a side of the second initial sub-trace 262 close to the first display region A1 in the first direction D1. The first initial sub-trace 261 may be electrically connected with a first initial adapter electrode 211 through two eighteenth vias V18 disposed vertically. The second initial sub-trace 262 may be electrically connected with a second initial adapter electrode 212 through two twentieth vias V20 disposed vertically.

In some examples, as shown in FIGS. 7D to 7F, the first output adapter electrode 251 may be electrically connected with a second scan line (e.g. RST1 (n)) through two thirteenth vias V13 disposed side by side, and may also be electrically connected with a first scan line (e.g. GL (n−1)) electrically connected to a previous row of pixel circuits. The second output adapter electrode 252 may be electrically connected with a first initial signal line INIT1 through two twenty-second vias V22 disposed vertically. The third output adapter electrode 253 may be electrically connected with a first scan line (e.g. GL (n)) through two fourteenth vias V14 disposed vertically, and may also be electrically connected with a second scan line (e.g. RST1 (n+1)) electrically connected to a next row of pixel circuits through two sixteenth vias V16 disposed side by side. The fourth output adapter electrode 254 may be electrically connected with a light emitting control line (e.g. EML (n)) through two fifteenth vias V15 disposed vertically. The fifth output adapter electrode 255 may be electrically connected with a second initial signal line INIT2 through two twenty-fourth vias V24 disposed vertically. The sixth output adapter electrode 256 may be electrically connected with a first initial adapter electrode 211 through two seventeenth vias V17 disposed vertically. The seventh output adapter electrode 257 may be electrically connected with a scan output connection line 221 through two twenty-sixth vias V26 disposed vertically. The eighth output adapter electrode 258 may be electrically connected with a light emitting control output connection line 222 through two twenty-fifth vias V25 disposed vertically. The ninth output adapter electrode 259 may be electrically connected with a second initial adapter electrode 212 through two nineteenth vias V19 disposed vertically.

In the present disclosure, being disposed side by side refers to being arranged along the first direction D1, and being disposed vertically refers to being arranged along the second direction D2.

In some examples, as shown in FIGS. 7D to 7F, the first connection electrode 237 may be electrically connected with an end of a first electrostatic conductive line 201 through an eleventh via V11, and may also be electrically connected with a first initial signal line INIT1 through a twenty-first via V21. The second connection electrode 238 may be electrically connected with another end of the first electrostatic conductive line 201 through a twelfth via V12, and may also be electrically connected with the second initial signal line INIT2 through a twenty-third via V23. In this example, a first electrode of the first electrostatic conduction control transistor M1 may be electrically connected with a first initial signal line INIT1, a second electrode of the first electrostatic conduction control transistor M1 may be electrically connected with a first electrode of the second electrostatic conduction control transistor M2, and a second electrode of the second electrostatic conduction control transistor M2 may be electrically connected with a second initial signal line INIT2. When the first electrostatic conduction control transistor M1 and the second electrostatic conduction control transistor M2 are simultaneously turned on, the first initial signal line INIT1 and the second initial signal line INIT2 may be conductive to each other. When at least one of the first electrostatic conduction control transistor M1 and the second electrostatic conduction control transistor M2 is turned off, the first initial signal line INIT1 and the second initial signal line INIT2 are disconnected.

In some implementations, before the third conductive layer is manufactured, long wires of the first conductive layer and the second conductive layer are prone to accumulation of static electricity because there is no way to interconnect other signal traces. When the first conductive layer and the second conductive layer are connected with an active layer of a transistor through the third conductive layer, since a resistance value of the active layer where a channel is formed changes from small to large, static electricity is easy to be released at a position where the resistance value changes, resulting in damage to the transistor. In this example, formation of a static electricity consumption circuit is controlled by providing the first electrostatic conductive line in the peripheral region and forming the first electrostatic conduction control transistor M1 and the second electrostatic conduction control transistor M2 with the first scan line and the light emitting control line. In some examples, when there is no static electricity accumulated in the first scan line or the light emitting control line, both the first electrostatic conduction control transistor M1 and the second electrostatic conduction control transistor M2 are turned off, and the first initial signal line INIT1 and the second initial signal line INIT2 are turned off. When static electricity is accumulated in the first scan line and the light emitting control line, the first electrostatic conduction control transistor M1 and the second electrostatic conduction control transistor M2 are turned on, and the first initial signal line INIT1 and the second initial signal line INIT2 are conductive to each other, which may form the static electricity consumption circuit, so that static electricity is not easily accumulated at a tip of the initial signal line, but is consumed in the static electricity consumption circuit, thereby avoiding static electricity accumulated in the long wire of the second conductive layer from being conducted to the semiconductor layer through the third conductive layer to burn the transistors.

In this example, static electricity generated before a fourth conductive layer is manufactured may be consumed by the static electricity consumption circuit formed by the first electrostatic conduction control transistor M1 and the second electrostatic conduction control transistor M2. In a normal display process after the manufacturing process is accomplished, according to an operation timing of the pixel circuit, the scan signal provided by the first scan line and the light emitting control signal provided by the light emitting control line are not simultaneously the low level. Therefore, the first electrostatic conduction control transistor M1 and the second electrostatic conduction control transistor M2 are not simultaneously turned on during the normal display process. During the normal display process, the first initial signal line INIT1 and the second initial signal line INIT2 are not conductive to cause a short circuit, thereby ensuring a normal display function.

(7) A fourth insulation layer and a fifth insulation layer are formed. In some examples, a fourth insulation thin film is deposited on the base substrate 100 where the aforementioned patterns are formed to form a fourth insulation layer 104. Subsequently, a fifth insulation thin film is coated and patterned through a patterning process to form a fifth insulation layer 105. In some examples, after a via or groove is formed in the fifth insulation layer 105, the fourth insulation layer 104 may be etched to form a via or groove provided in the fourth insulation layer 104 to expose a surface of the third conductive layer 23.

FIG. 7G is a schematic diagram of the circuit structure layer after a fifth insulation layer is formed in FIG. 5. In some examples, as shown in FIG. 7G, a fifth insulation layer 105 of the first display region A1 may be provided with a plurality of vias, which may include a thirty-first via V31 to a thirty-third via V33, for example. A fifth insulation layer 105 and a fourth insulation layer 104 within the thirty-first via V31 are removed to expose a surface of the third pixel connection electrode 233 located in the third conductive layer 23. A fifth insulation layer 105 and a fourth insulation layer 104 within the thirty-second via V32 are removed to expose a surface of the fourth pixel connection electrode 234 located in the third conductive layer 23. A fifth insulation layer 105 and a fourth insulation layer 104 within the thirty-third via V33 are removed to expose a surface of the fifth pixel connection electrode 235 located in the third conductive layer 23.

In some examples, as shown in FIG. 7G, a fifth insulation layer 105 of the peripheral region BB may be provided with a plurality of vias and a plurality of grooves, which may include a thirty-fourth via V34 to a fifty-first via V41, a first groove V42 and a second groove V43, for example. Fifth insulation layers 105 and fourth insulation layers 104 within the thirty-fourth via V34 to the forty-first via V41 are removed to expose a surface of the output adapter electrode located in the third conductive layer 23. A fifth insulation layer 105 and a fourth insulation layer 104 within the first groove V42 are removed to expose a surface of the first initial sub-trace 261 located in the third conductive layer 23. A fifth insulation layer 105 and a fourth insulation layer 104 within the second groove V43 are removed to expose a surface of the second initial sub-trace 262 located in the third conductive layer 23.

(8) A fourth conductive layer is formed. In some examples, a fourth conductive thin film is deposited on the base substrate 100 where the aforementioned patterns are formed, and the fourth conductive thin film is patterned by a patterning process to form a fourth conductive layer 24.

In some examples, as shown in FIG. 5, a fourth conductive layer 24 of the first display region A1 may include a plurality of anode connection electrodes (e.g., a first anode connection electrode 241), a plurality of first power supply lines 242, and a plurality of data lines 243. Both the first power supply line 242 and the data line 243 may extend along the second direction D2, and may be adjacent in the first direction D1. The first anode connection electrode 241 may be electrically connected with the fifth pixel connection electrode 235 through the thirty-third via V33, thereby achieving an electrical connection to the second electrode of the sixth transistor of the first pixel circuit. A data line 243 may be electrically connected with the third pixel connection electrode 233 through the thirty-first via V31, thereby achieving electrical connection with the first electrode of the fourth transistor of the first pixel circuit. A first power supply line 242 may be electrically connected with the fourth pixel connection electrode 234 through the thirty-second via V32, thereby achieving electrical connection with the first electrode of the fifth transistor of the first pixel circuit and the second capacitor plate of the storage capacitor. For example, the first power supply line 242 may extend to the lower bezel region along the second direction D2, and be electrically connected to peripheral power supply traces provided in the lower bezel region, so as to be configured to transmit a first voltage signal.

In some examples, as shown in FIG. 5, a fourth conductive layer 24 of the peripheral region BB may include a third initial sub-trace 263, a fourth initial sub-trace 264, and a plurality of output adapter lines (including, for example, a first output adapter line 271 to a fourth output adapter line 274). The third initial sub-trace 263 and the fourth initial sub-trace 264 may extend along the second direction D2, and the third initial sub-trace 263 may be located on a side of the fourth initial sub-trace 264 close to the first display region A1 in the first direction D1. An orthographic projection of the third initial sub-trace 263 on the base substrate may be overlapped with an orthographic projection of the first initial sub-trace 261 on the base substrate. The third initial sub-trace 263 may be electrically connected with the first initial sub-trace 261 through the first groove V42. An orthographic projection of the fourth initial sub-trace 264 on the base substrate may be overlapped with an orthographic projection of the second initial sub-trace 262 on the base substrate. The fourth initial sub-trace 264 may be electrically connected with the second initial sub-trace 262 through the second groove V43. In this example, the first initial peripheral trace may be a double-layered trace including a first initial sub-trace 261 and a third initial sub-trace 263; and the second initial peripheral trace may be a double-layered trace including a second initial sub-trace 262 and a fourth initial sub-trace 264.

In some examples, as shown in FIGS. 7F, 7G, and 5, the first output adapter line 271 may be electrically connected with the second output adapter electrode 252 through the thirty-fourth via V34, and may also be electrically connected with the sixth output adapter electrode 256 through the thirty-eighth via V38, thereby achieving electrical connection of a first initial signal line INIT1 with a first initial peripheral trace. The second output adapter line 272 may be electrically connected with the third output adapter electrode 253 through the thirty-fifth via V35, and may also be electrically connected with the seventh output adapter electrode 257 through the thirty-ninth via V39, thereby achieving electrical connections of a scan output line with a first scan line (e.g. GL (n)) and a second scan line (e.g. RST1 (n+1)). The third output adapter line 273 may be electrically connected with the fourth output adapter electrode 254 through the thirty-sixth via V36, and may also be electrically connected with the eighth output adapter electrode 258 through the fortieth via V40, thereby achieving electrical connection of a light emitting control output line with a light emitting control line (e.g., EML (n)). The fourth output adapter line 274 may be electrically connected to the fifth output adapter electrode 255 through the thirty-seventh via V37, and may also be electrically connected with the ninth output adapter electrode 259 through the forty-first via V41, thereby achieving electrical connection of a second initial signal line INIT2 with a second initial peripheral trace. However, the embodiment is not limited thereto. In some other examples, the first to fourth output adapter lines may be disposed in the third conductive layer.

So far, the circuit structure layer of the display substrate is manufactured. At this point, the second display region A2 may include the base substrate 100, and the first insulation layer 101, the second insulation layer 102, the third insulation layer 103, the fourth insulation layer 104, and the fifth insulation layer 105 which are stacked on the base substrate 100. In some examples, film layer structures of a second pixel circuit and a dummy pixel circuit of the second circuit region A12 of the first display region A1 may be similar to a film layer structure of the first pixel circuit, which is not be repeated here.

(9) At least one transparent conductive layer and a light emitting structure layer are formed sequentially, wherein the light emitting structure layer may include an anode layer, a pixel definition layer, an organic light emitting layer, and a cathode layer.

In some exemplary implementations, a transparent conductive layer is taken as an example for description. A first planarization thin film is coated on the base substrate on which the aforementioned patterns are formed, and the first planarization thin film is patterned through a patterning process to form a first planarization layer. A transparent conductive thin film is deposited on the base substrate on which the aforementioned patterns are formed, and the transparent conductive thin film is patterned through a patterning process to form a transparent conductive layer. The transparent conductive layer may include a plurality of transparent conductive lines electrically connecting a second pixel circuit of the first display region with a second light emitting element of the second display region. Subsequently, a second planarization thin film is coated on the base substrate on which the aforementioned patterns are formed, and the second planarization thin film is patterned through a patterning process to form a second planarization layer. After that, an anode thin film is deposited on the base substrate on which the aforementioned patterns are formed, and the anode thin film is patterned through a patterning process to form an anode layer. Subsequently, a pixel definition thin film is coated on the base substrate on which the aforementioned patterns are formed, and a pixel definition layer is formed through mask, exposure, and development processes. The pixel definition layer is provided with a plurality of pixel openings exposing the anode layer. Subsequently, an organic light emitting layer is formed within the aforementioned pixel openings, and an organic light emitting layer is connected with an anode. After that, a cathode thin film is deposited, and the cathode thin film is patterned through a patterning process to form a cathode layer, and the cathode layer is electrically connected with the organic light emitting layer and a second power supply line, respectively. In some examples, an encapsulation structure layer is formed on the cathode layer. The encapsulation structure layer may include a stacked structure of inorganic material/organic material/inorganic material. In some other examples, a plurality of transparent conductive layers (e.g. three transparent conductive layers) may be provided, and a plurality of transparent conductive lines may be arranged in the plurality of transparent conductive layers. At least one planarization layer may be disposed between adjacent transparent conductive layers.

In some exemplary implementations, the first conductive layer 21, the second conductive layer 22, the third conductive layer 23 and the fourth conductive layer 24 may be made of a metal material, such as any one or more of argentum (Ag), copper (Cu), aluminum (Al), and molybdenum (Mo), or an alloy material of the abovementioned metals, such as an Aluminum Neodymium alloy (AlNd) or a Molybdenum Niobium alloy (MoNb), and may be in a single-layered structure or a multi-layered composite structure, such as Mo/Cu/Mo. The first insulation layer 101, the second insulation layer 102, the third insulation layer 103, and the fourth insulation layer 104 may be made of any one or more of Silicon Oxide (SiOx), Silicon Nitride (SiNx), and Silicon Oxynitride (SiON), and may be a single layer, a multi-layer, or a composite layer. The first insulation layer 101 and the second insulation layer 102 may be referred to as Gate Insulation (GI) layers, the third insulation layer 103 may be referred to as an Interlayer Dielectric (ILD) layer, and the fourth insulation layer 104 may be referred to as a passivation layer. The fifth insulation layer 105, the first planarization layer, and the second planarization layer may be made of an organic material, such as polyimide, acrylic, or polyethylene terephthalate. The pixel definition layer may be made of an organic material, such as polyimide, acrylic, or polyethylene terephthalate. The anode layer may be made of a reflective material such as a metal, and the cathode layer may be made of a transparent conductive material. However, the embodiment is not limited thereto.

The structure of the display substrate and the manufacturing process for a display substrate in the embodiments of the present disclosure are merely illustrative. In some exemplary implementations, a corresponding structure may be changed and a patterning process may be added or removed according to actual needs. The manufacturing process in this exemplary embodiment may be implemented using an existing mature manufacturing equipment, and is compatible well with an existing manufacturing process, simple in process implementation, easy to implement, high in a production efficiency, low in a production cost, and high in a yield.

In the display substrate according to the embodiment, the first electrostatic conductive line is disposed in the peripheral region, and the first electrostatic conductive line is located in the semiconductor layer, so that no additional manufacturing operation is needed. The first electrostatic conductive line may coordinate with the first scan line and the light emitting control line to form an electrostatic conduction control transistor, without occupying original wiring space of the display substrate, and the original wiring can be used to form an static electricity consumption circuit, which consumes static electricity only when there is static electricity, thereby reducing a probability of poor electrostatic discharge in the display region, improving a yield of the display substrate, without affecting normal display of the display substrate.

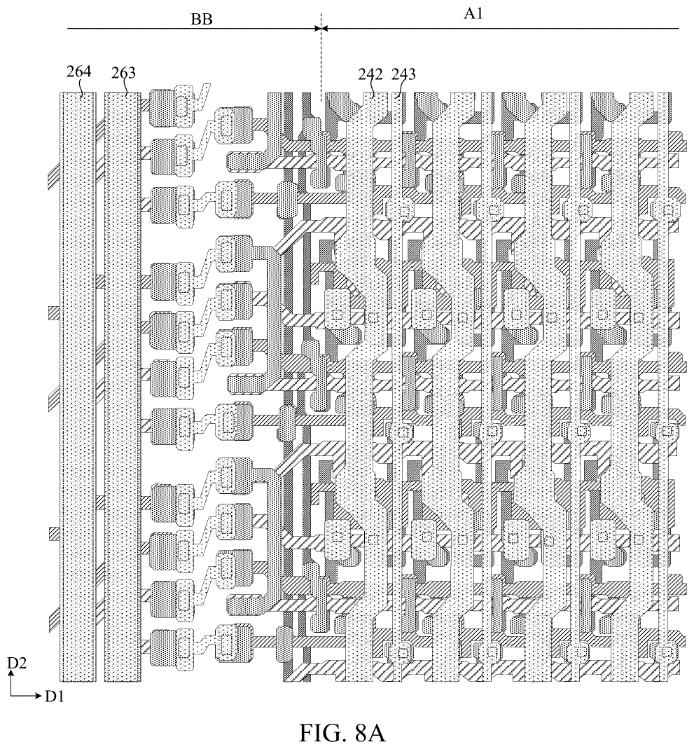

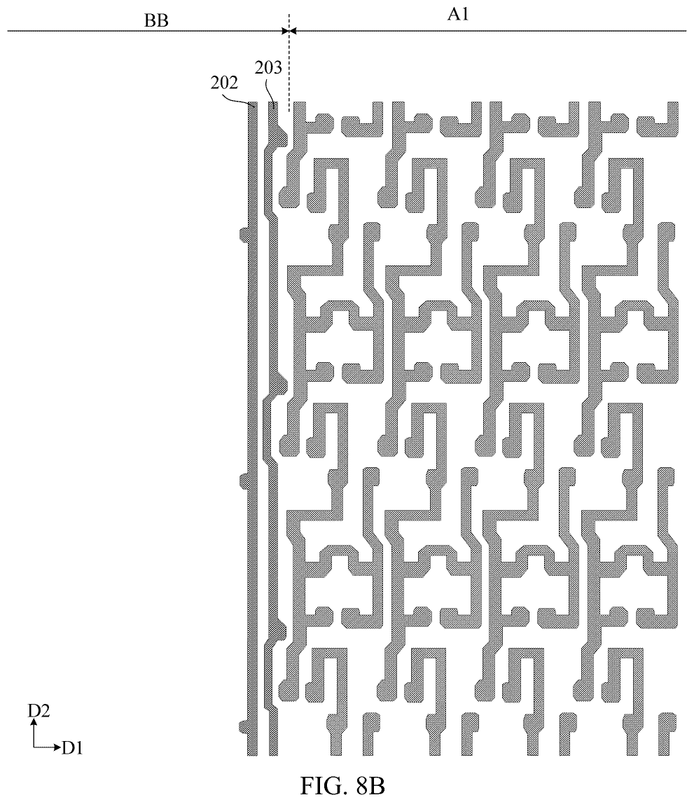

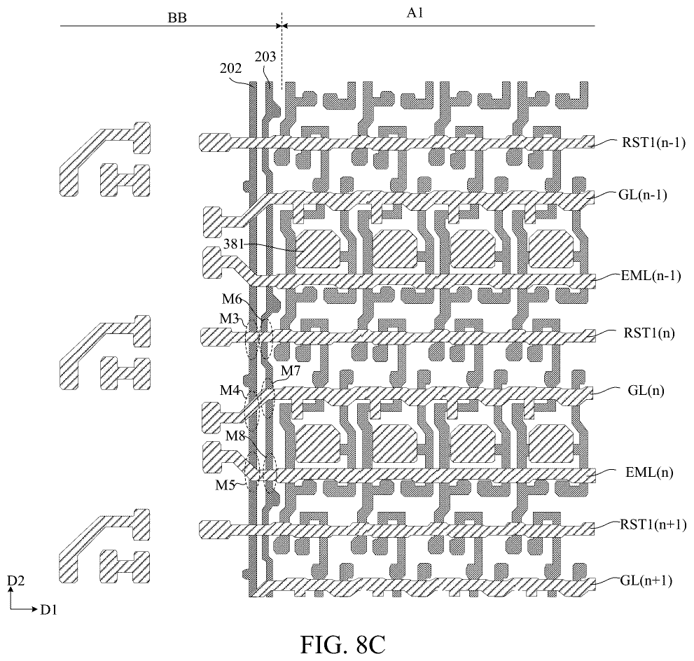

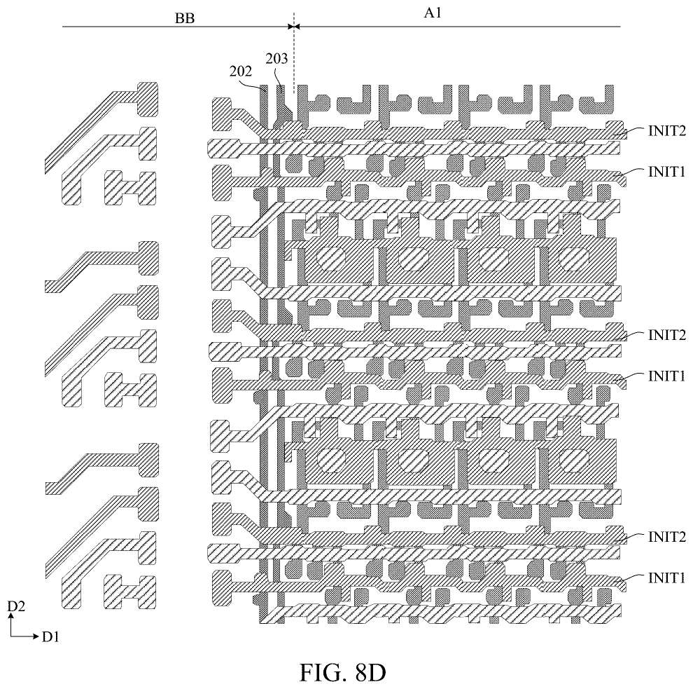

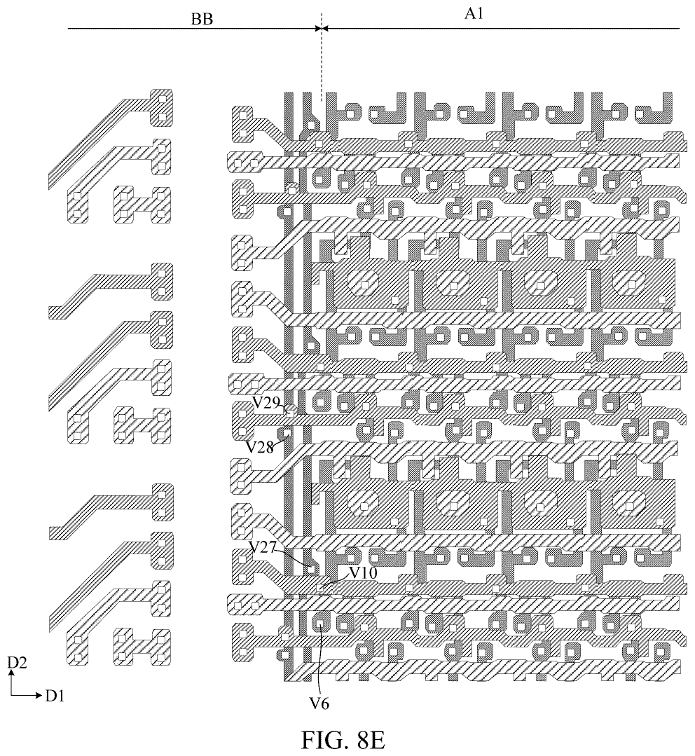

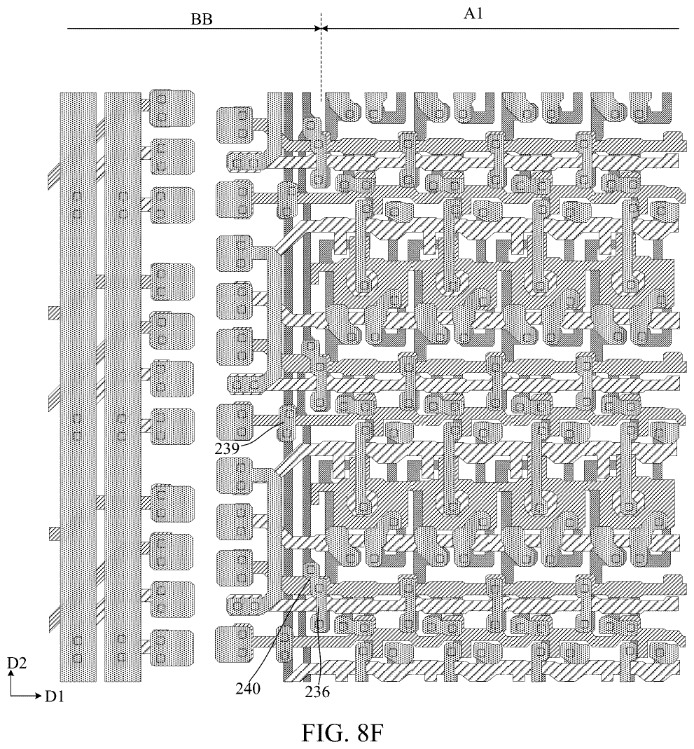

FIG. 8A is another enlarged diagram of a partition of a circuit structure layer of the region CC in FIG. 1. FIG. 8B is a schematic diagram of the circuit structure layer after a semiconductor layer is formed in FIG. 8A. FIG. 8C is a schematic diagram of the circuit structure layer after a first conductive layer is formed in FIG. 8A. FIG. 8D is a schematic diagram of the circuit structure layer after a second conductive layer is formed in FIG. 8A. FIG. 8E is a schematic diagram of the circuit structure layer after a third insulation layer is formed in FIG. 8A. FIG. 8F is a schematic diagram of the circuit structure layer after a third conductive layer is formed in FIG. 8A.

In some examples, as shown in FIGS. 8A and 8B, the semiconductor layer 20 of the peripheral region BB may at least include a second electrostatic conductive line 202 and a third electrostatic conductive line 203. Both the second electrostatic conductive line 202 and the third electrostatic conductive line 203 extend along the second direction D2, and the second electrostatic conductive line 202 is located on a side of the third electrostatic conductive line 203 away from the first display region A1 in the first direction D1.

In some examples, as shown in FIG. 8C, the ends of the first scan line, the second scan line, and the light emitting control line may extend to the peripheral region BB. An orthographic projection of the second electrostatic conductive line 202 on the base substrate may be overlapped with orthographic projections of at least one first scan line, at least one second scan line, and at least one light emitting control line on the base substrate. An orthographic projection of the third electrostatic conductive line 203 on the base substrate may be overlapped with orthographic projections of at least one first scan line, at least one second scan line, and at least one light emitting control line on the base substrate. An overlapping region of the second electrostatic conductive line 202 with an orthographic projection of a second scan line (e.g. RST1 (n)) on the base substrate may serve as a channel region of a third electrostatic conduction control transistor M3, and an overlapping region of the second scan line with the second electrostatic conductive line 202 may serve as a gate of the third electrostatic conduction control transistor M3. An overlapping region of the second electrostatic conductive line 202 with an orthographic projection of a first scan line (e.g. GL (n)) on the base substrate may serve as a channel region of a fourth electrostatic conduction control transistor M4, and an overlapping region of the first scan line with the second electrostatic conductive line 202 may serve as a gate of the fourth electrostatic conduction control transistor M4. An overlapping region of the second electrostatic conductive line 202 with an orthographic projection of a light emitting control line (e.g., EML (n)) on the base substrate may serve as a channel region of a fifth electrostatic conduction control transistor M5, and an overlapping region of the light emitting control line with the second electrostatic conductive line 202 may serve as a gate of the fifth electrostatic conduction control transistor M5. Similarly, the third electrostatic conductive line 203 may be overlapped with a second scan line (e.g. RST1 (n)) to form a channel region of the sixth electrostatic conduction control transistor M6, the third electrostatic conductive line 203 may be overlapped with a first scan line (e.g. GL (n)) to form a channel region of the seventh electrostatic conduction control transistor M7, and the third electrostatic conductive line 203 may be overlapped with a light emitting control line (e.g. EML (n)) to form a channel region of the eighth electrostatic conduction control transistor M8.

In some examples, as shown in FIG. 8D, the first initial signal line INIT1 and the second initial signal line INIT2 located in the second conductive layer may extend to the peripheral region BB. The orthographic projection of the second electrostatic conductive line 202 on the base substrate may be overlapped with the orthographic projections of the first initial signal line INIT1 and the second initial signal line INIT2 on the base substrate, and the orthographic projection of the third electrostatic conductive line 203 on the base substrate may be overlapped with the orthographic projections of the first initial signal line INIT1 and the second initial signal line INIT2 on the base substrate.

In some examples, as shown in FIG. 8E, the third insulation layer of the peripheral region BB may be provided with a plurality of vias, which may include a twenty-seventh via V27 to a twenty-ninth via V29, for example. A third insulation layer, a second insulation layer, and a first insulation layer within the twenty-seventh via V27 are removed to expose a surface of the third electrostatic conductive line 203 located in the semiconductor layer 20. A third insulation layer, a second insulation layer, and a first insulation layer within the twenty-eighth via V28 are removed to expose a surface of the second electrostatic conductive line 202 located in the semiconductor layer 20. A third insulation layer within the twenty-ninth via V29 is removed to expose a surface of a first initial signal line INIT1 located in the second conductive layer 22.

In some examples, as shown in FIGS. 8E and 8F, the third conductive layer of the peripheral region BB may include a third connection electrode 239 and a fourth connection electrode 240. The third connection electrode 239 may be electrically connected with the second electrostatic conductive line 202 through the twenty-eighth via V28, and may also be electrically connected with a first initial signal line INIT1 through the twenty-ninth via V29. In this example, at least two first initial signal lines INIT1 may be electrically connected with the second electrostatic conductive line 202. A second electrostatic conductive line 202 connected between two adjacent first initial signal lines INIT1 may form three electrostatic conductive control transistors (i.e., M3 to M5). During the manufacturing process for a display substrate, when same static electricity is accumulated in a first scan line (e.g. GL (n)), a second scan line (e.g. RST1 (n)) and a light emitting control line (e.g. EML (n)), such that the third to fifth electrostatic conduction control transistors M3 to M5 are turned on simultaneously, at least two second initial signal lines may be conductive, thereby forming an static electricity consumption circuit to consume static electricity. During the normal display process, the third to fifth electrostatic conduction control transistors M3 to M5 are not turned on simultaneously due to differences in signals transmitted by the first scan line, the second scan line and the light emitting control line, so that at least two first initial signal lines are not conductive. In addition, signals of a same type are transmitted by the plurality of first initial signal lines INIT1, which does not affect the display even if the first initial signal lines INIT1 are conductive to each other.

In some examples, as shown in FIGS. 8E and 8F, the sixth pixel connection electrode 236 of the third conductive layer of the first display region A1 may be electrically connected with the first region of the seventh active layer of the seventh transistor through the sixth via V6, and may also be electrically connected with a second initial signal line INIT2 through the tenth via V10. The fourth connection electrode 240 may be electrically connected with the third electrostatic conductive line 203 through the twenty-seventh via V27. The sixth pixel connection electrode 236 and the fourth connection electrode 240 may be in an integral structure. In this example, at least two second initial signal lines INIT2 may be electrically connected with the third electrostatic conductive line 203. A third electrostatic conductive line 203 connected between two adjacent second initial signal lines INIT2 may form three electrostatic conductive control transistors (i.e., M6 to M8). During the manufacturing process for a display substrate, when same static electricity is accumulated in a first scan line (e.g. GL (n)), a second scan line (e.g. RST1 (n)) and a light emitting control line (e.g. EML (n)) such that the sixth to eighth electrostatic conduction control transistors M6 to M8 are turned on simultaneously, at least two second initial signal lines may be conductive, thereby forming an static electricity consumption circuit to consume static electricity. During the normal display process, the sixth to eighth electrostatic conduction control transistors M6 to M8 are not turned on simultaneously due to differences in signals transmitted by the first scan line, the second scan line and the light emitting control line, so that at least two initial signal lines are not conductive. In addition, signals of a same type are transmitted by the plurality of second initial signal lines INIT2, which does not affect the display even if the second initial signal lines INIT2 are conductive to each other.

With regard to remaining film layer structures of the display substrate in this embodiment, reference may be made to the description of the aforementioned embodiments, which will not be repeated here.

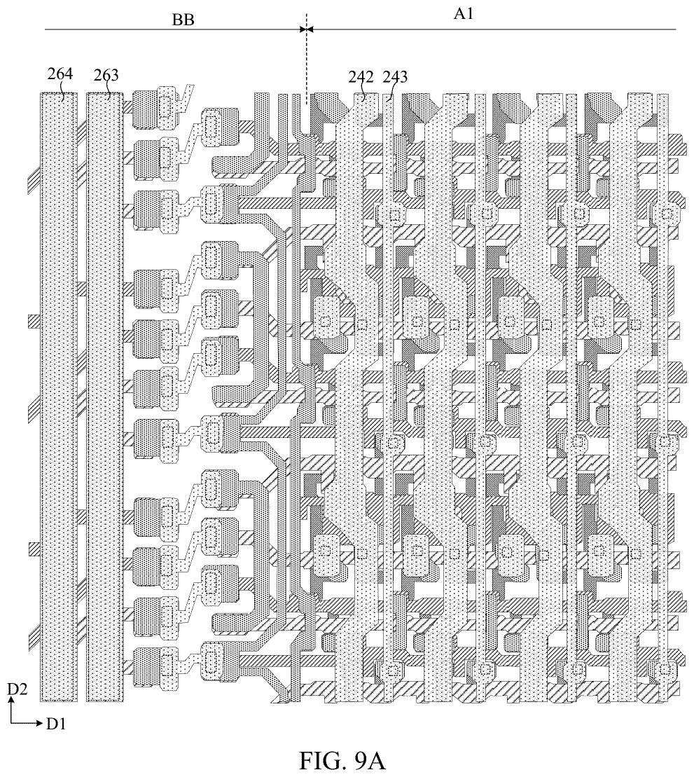

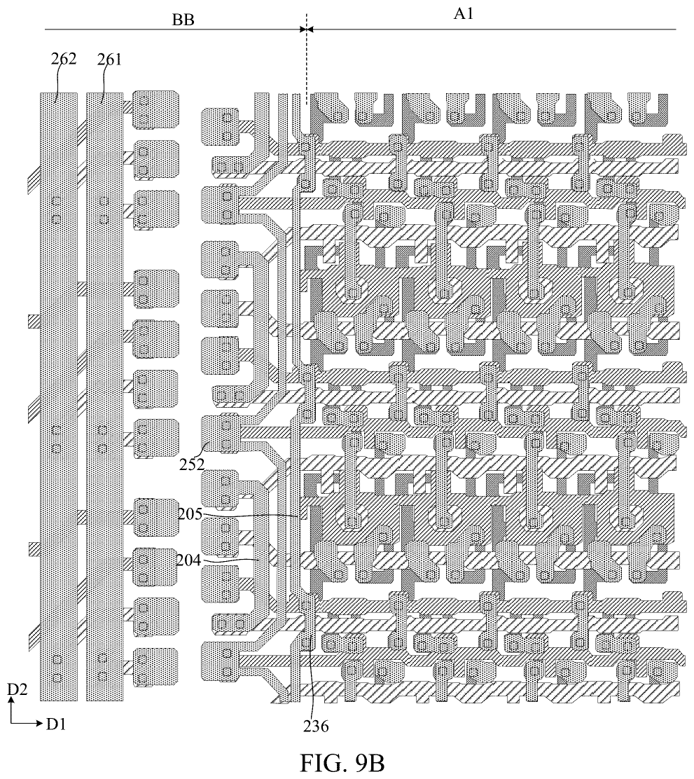

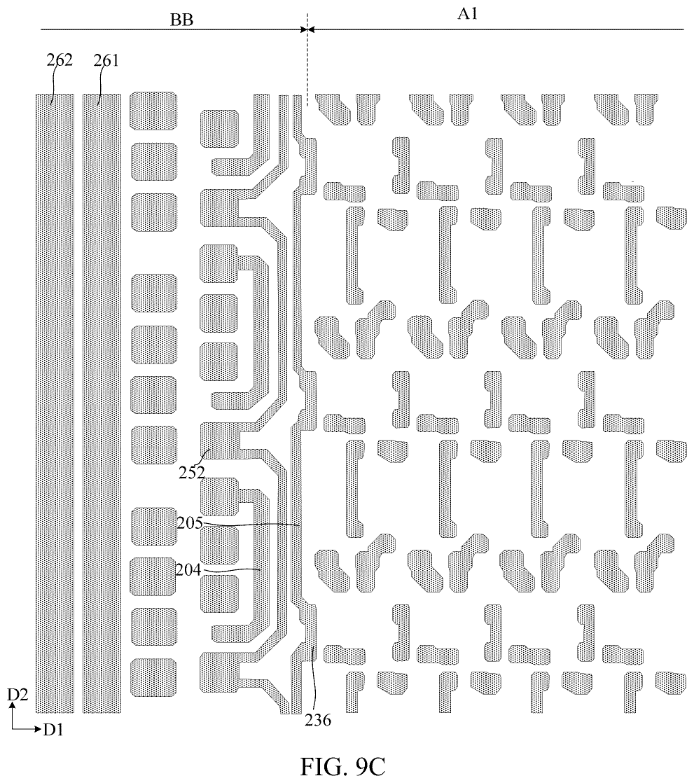

FIG. 9A is another partially enlarged diagram of a partition of the circuit structure layer of the region CC in FIG. 1. FIG. 9B is a schematic diagram of the circuit structure layer after a third conductive layer is formed in FIG. 9A. FIG. 9C is a schematic diagram of the third conductive layer in FIG. 9B.

In some examples, as shown in FIGS. 9A to 9C, the third conductive layer of the peripheral region BB may include a fourth electrostatic conductive line 204 and a fifth electrostatic conductive line 205. The fourth electrostatic conductive line 204 and the fifth electrostatic conductive line 205 may extend along the second direction D2, and the fifth electrostatic conductive line 205 may be located on a side of the fourth electrostatic conductive line 204 close to the first display region A1 in the first direction D1. A fourth electrostatic conductive line 204 may be connected to adjacent second output adapter electrode 252, thereby achieving electrical connection with an adjacent first initial signal line INIT1. A plurality of fourth electrostatic conductive lines 204 and a plurality of second output adapter electrodes 252 may be in an integral structure. A fifth electrostatic conductive line 205 may be electrically connected to an adjacent sixth pixel connection electrode 236, thereby achieving electrical connection with an adjacent second initial signal line INIT2. A plurality of fifth electrostatic conductive lines 205 and a plurality of sixth pixel connection electrodes 236 may be in an integral structure.

In this example, at least two first initial signal lines INIT1 may be electrically connected through a fourth electrostatic conductive line 204 to form an static electricity consumption circuit, and at least two second initial signal lines INIT2 may be electrically connected through a fifth electrostatic conductive line 205 to form an static electricity consumption circuit. In this way, static electricity accumulated in the first initial signal line and the second initial signal line is not gathered at a tip of a trace, and can be consumed through the static electricity consumption circuit, thereby consuming the static electricity generated during the manufacturing process, and effectively reducing an ESD risk of the display region.

With regard to remaining film layer structures of the display substrate in this embodiment, reference may be made to the description of the aforementioned embodiments, which will not be repeated here.

In other examples, the abovementioned embodiments may be combined with each other. For example, at least two of the first to fifth electrostatic conductive lines may be disposed in the peripheral region of the display substrate. For example, the left bezel region of the display substrate may be provided with a first electrostatic conductive line, and the right bezel region may be provided with a second electrostatic conductive line and a third electrostatic conductive line. Or, the left bezel region may be provided with a second electrostatic conductive line and a third electrostatic conductive line, and the right bezel region may be provided with a fourth electrostatic conductive line and a fifth electrostatic conductive line. However, the embodiment is not limited thereto.

FIG. 10 is a schematic sectional view of a partition of a display substrate according to at least one embodiment of the present disclosure. In some examples, as shown in FIG. 10, in a direction perpendicular to the display substrate, a first display region A1 may include a base substrate 100, and a circuit structure layer 200, three transparent conductive layers (e.g. a first transparent conductive layer 31, a second transparent layer 32, and a third transparent conductive layer 33), a light emitting structure layer 400, and an encapsulation structure layer 500 which are sequentially disposed on the base substrate 100. The circuit structure layer 200 may include a semiconductor layer 20, a first insulation layer 101, a first conductive layer 21, a second insulation layer 102, a second conductive layer 22, a third insulation layer 103, a third conductive layer 23, a fourth insulation layer 104, a fifth insulation layer 105, and a fourth conductive layer 24 that are sequentially disposed on the base substrate 100. A sixth insulation layer 106 is provided between the first transparent conductive layer 31 and the circuit structure layer 200, a seventh insulation layer 107 is provided between the first transparent conductive layer 31 and the second transparent conductive layer 32, and an eighth insulation layer 108 is provided between the second transparent conductive layer 32 and the third transparent conductive layer 33. A ninth insulation layer 109 is provided between the third transparent conductive layer 33 and the light emitting structure layer 400. The second display region A2 may include a base substrate 100, and a first insulation layer 101 to a sixth insulation layer 106, a first transparent conductive layer 31, a seventh insulation layer 107, a second transparent conductive layer 32, an eighth insulation layer 108, a third transparent conductive layer 33, a ninth insulation layer 109, a light emitting structure layer 400, and an encapsulation structure layer 500 that are sequentially disposed on the base substrate 100. In some examples, all of the first insulation layer 101 to the fourth insulation layer 104 may be inorganic insulation layers, and all of the fifth insulation layer 105 to the ninth insulation layer 109 may be organic insulation layers, for example, may be referred to as a planarization layer.

In some examples, the first transparent conductive layer 31 may include a second anode connection electrode and a plurality of first conductive lines, which are located in the first display region A1. The first conductive line may extend from the first display region A1 to the second display region A2 to electrically connect a second pixel circuit to a second light emitting element. A second anode connection electrode of the first display region A1 may be electrically connected with a first anode connection electrode of the fourth conductive layer. The second transparent conductive layer 32 may include a plurality of third anode connection electrodes, and a plurality of second conductive lines. A third anode connection electrode of the first display region A1 may be electrically connected with the second anode connection electrode. A third anode connection electrode of the second display region A2 may be electrically connected with a first conductive line. The third transparent conductive layer 33 may include a plurality of fourth anode connection electrodes, and a plurality of third conductive lines. A fourth anode connection electrode of the first display region A1 may be electrically connected with the third anode connection electrode. A fourth anode connection electrode of the second display region A2 may be electrically connected with a second conductive line. The light emitting structure layer 400 may include an anode layer 41 (e.g. an anode 41a of the first light emitting element, an anode 41b of the second light emitting element), an organic light emitting layer 42 (e.g. an organic light emitting layer 42a of the first light emitting element, an organic light emitting layer 42b of the second light emitting element), a cathode layer 43, and a pixel definition layer 44. The anode 41a of the first light emitting element may be electrically connected with a fourth anode connection electrode of the third transparent conductive layer 33. The anode 41b of the second light emitting element may be electrically connected with a third conductive line of the third transparent conductive layer 33 or a fourth anode connection electrode of the second display region A2.

In some examples, as shown in FIG. 10, since the second display region A2 is a light transmitting region, all positions within the second display region A2 are light transmitting positions except the anode layer. Moreover, the anode layer has a planarization surface. Self luminescent light of the second display region A2 and external light (as shown by dashed lines in FIG. 10) reach an interface between the base substrate 100 and the air through refraction and reflection. At the interface between the base substrate 100 and the air, the light is totally reflected, and the totally reflected light (as shown by dotted lines in FIG. 10) reaches the first display region A1, resulting in light leakage in some sub-pixels of the first display region A1, causing sub-pixels at corresponding positions to darken, and forming a progressive dark circle.

In some exemplary implementations, the anode of the second light emitting element may have a bottom, and a sidewall extending from the bottom to a side away from the base substrate. In this example, the anode of the second light emitting element may be in a groove shape, so that light emitted from the second light emitting element is reflected by the sidewall of the anode, light refracted to a non-display side is reduced, and the problem of the progressive dark circle is improved. The anode of the first light emitting element may be in a shape similar to a shape of the anode of the second light emitting element, or the anode of the first light emitting element may have a planarization surface. The embodiment is not limited thereto.

In some exemplary implementations, at least one first organic insulation layer between the light emitting structure layer and the circuit structure layer may have at least one first anode groove. An orthographic projection of the anode of the second light emitting element on the base substrate may cover an orthographic projection of the first anode groove of the first organic insulation layer on the base substrate. The pixel definition layer may be located on a side of the anode layer away from the base substrate, and provided with a pixel opening exposing a surface of the anode of the second light emitting element. The orthographic projection of the first anode groove of the first organic insulation layer on the base substrate covers an orthographic projection of the pixel opening on the base substrate. In some examples, the first organic insulation layer may include at least one of the fifth to ninth insulation layers. In this example, the first anode groove formed by the first organic insulation layer may be utilized to make the anode of the second light emitting element be in a groove shape.

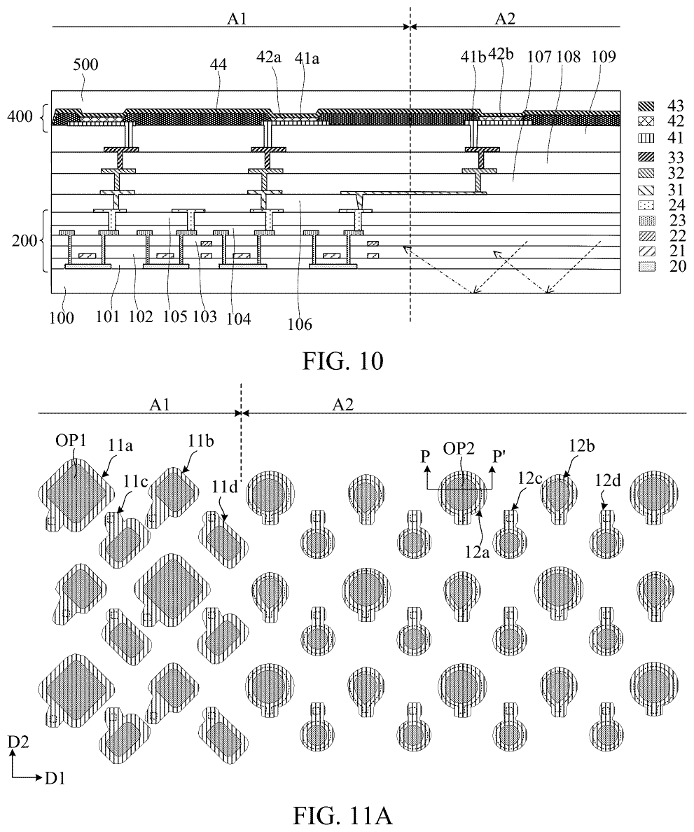

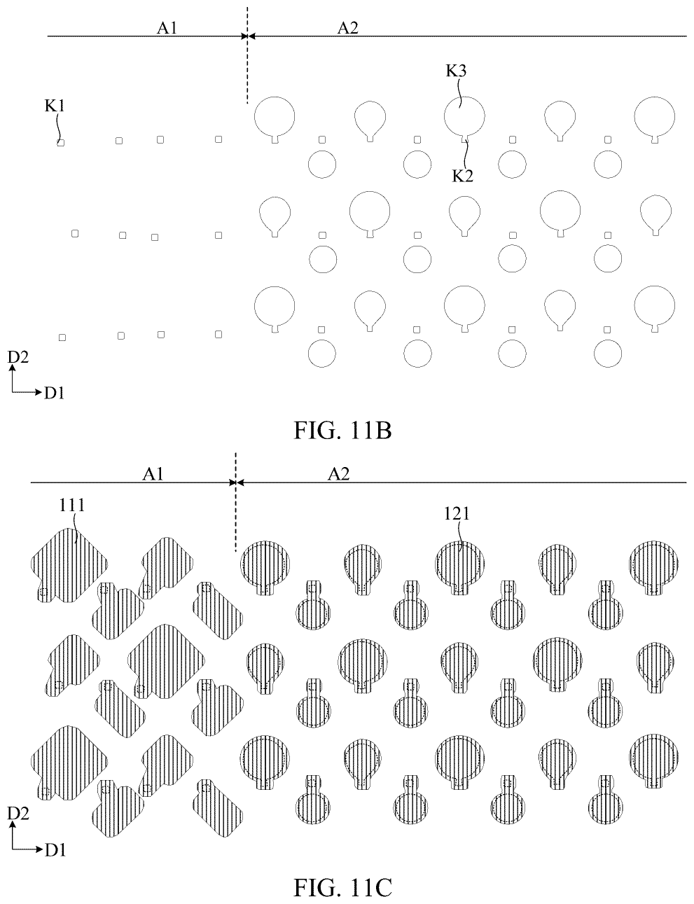

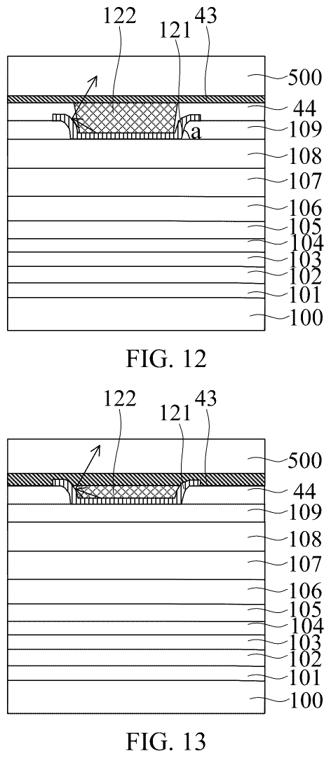

The description is made by taking the first organic insulation layer as the ninth insulation layer an example. FIG. 11A is a schematic top view of a partition of a display substrate according to at least one embodiment of the present disclosure. FIG. 11B is a schematic diagram of the display substrate after a ninth insulation layer is formed in FIG. 11A. FIG. 11C is a schematic diagram of the display substrate after an anode layer is formed in FIG. 11A. FIG. 12 is a cross-sectional view of a partition taken along a P-P′ direction in FIG. 11A.

In some examples, as shown in FIG. 11A, first light emitting elements of a first display region A1 may include a first light emitting element 11a emitting light of a first color, a first light emitting element 11b emitting light of a second color, and first light emitting elements 11c and 11d emitting light of a third color. The first light emitting elements 11a emitting light of the first color and the first light emitting elements 11b emitting light of the second color may be interleaved in one row along a first direction D1, and interleaved in one column in a second direction D2. The first light emitting elements 11c and 11d emitting light of the third color may be interleaved in one row along the first direction D1, and interleaved in one column in the second direction D2. A row of first light emitting elements 11c and 11d emitting light of the third color are located between two rows of first light emitting elements 11a emitting light of the first color and first light emitting elements 11b emitting light of the second color in the second direction D2. A column of first light emitting elements 11c and 11d emitting light of the third color are located between two columns of first light emitting elements 11a emitting light of the first color and first light emitting elements 11b emitting light of the second color in the first direction D1. In some examples, light emitting regions of the first light emitting elements 11a, 11b, 11c and 11d may be in a shape of rectangle in different sizes (e.g. a rounded rectangle). In some examples, the light of the first color may be blue light, the light of the second color may be red light, and the light of the third color may be green light. However, the embodiment is not limited thereto.

In some examples, as shown in FIG. 11A, second light emitting elements of a second display region A2 may include a second light emitting element 12a emitting light of the first color, a second light emitting element 12b emitting light of the second color, and second light emitting elements 12c and 12d emitting light of the third color. Arrangement of the second light emitting elements is the same as the arrangement of the first light emitting elements, which is not repeated here. Light emitting regions of the second light emitting elements 12a, 12c and 12d may be in a shape of circle or ellipse in different sizes, and a light emitting region of the second light emitting element 12b may be water drop-shaped. However, the embodiment is not limited thereto.

In some examples, the description is made by taking the first light emitting element 11a emitting light of the first color and the second light emitting element 12a emitting light of the first color as an example. As shown in FIGS. 11B and 12, a ninth insulation layer 109 of the first display region A1 may be provided with a first anode via K1, and a ninth insulation layer 109 within the first anode via K1 may be removed to expose a fourth anode connection electrode. A ninth insulation layer 109 of the second display region A2 may be provided with a second anode via K2 and a first anode groove K3. A second anode via K2 and a first anode groove K3 corresponding to the second light emitting element 12a emitting light of the first color may be communicated. A second anode via and a first anode groove corresponding to the second light emitting element emitting light of the third color may be not communicated. A ninth insulation layer 109 within the second anode via K2 is removed to expose a surface of the third transparent conductive layer. A ninth insulation layer 109 within the first anode groove K3 may be removed completely to expose a surface of an eighth insulation layer 108, or may be removed partially. A bottom surface of the first anode groove K3 may be a planarization surface, such that an anode formed within the first anode groove K3 may remain flat. However, the embodiment is not limited thereto.

In some examples, an included angle between a side surface of the first anode groove K3 and a plane in which the base substrate is located is a. For example, a may be greater than or equal to 30 degrees. By increasing a size of a, light reflection can be increased, and light reaching a non-display side of the display substrate can be minimized.

In some examples, as shown in FIG. 11C, an anode layer of the first display region A1 may at least include an anode 111 of the first light emitting element 11a. The anode 111 of the first light emitting element 11a may be electrically connected with a fourth anode connection electrode of the third transparent conductive layer through the first anode via K1. An anode layer of the second display region A2 may at least include an anode 121 of the second light emitting element 12a. The anode 121 of the second light emitting element 12a may be electrically connected with a fourth anode connection electrode or a third transparent conductive line located in the third transparent conductive layer through the second anode via K2. An orthographic projection of the anode 121 of the second light emitting element 12a on the base substrate may cover orthographic projections of the second anode via K2 and the first anode groove K3 on the base substrate.

In some examples, as shown in FIG. 11A, a pixel definition layer of the first display region A1 is provided with a first pixel opening OP1, and a pixel definition layer within the first pixel opening OP1 is removed to expose a surface of the anode 111. A pixel definition layer of the second display region A2 is provided with a second pixel opening OP2, and a pixel definition layer within the second pixel opening OP2 is removed to expose a surface of the anode 121. An orthographic projection of the second pixel opening OP2 on the base substrate may be within a range of an orthographic projection of the first anode groove K3 on the base substrate.

In some examples, as shown in FIG. 12, the anode 121 of the second light emitting element 12a may be formed in a groove shape, such that light emitted from the second light emitting element 12a is not refracted toward the base substrate of the display substrate, but is reflected to a display side after the sidewall of the anode 121 shading the light, thereby avoiding affecting transistor characteristics of the circuit structure layer of the first display region, and improving the progressive dark circle.

According to the display substrate in this example, no additional processing act is needed and cost is not increased. Moreover, by providing the groove in the first organic insulation layer below the anode, overall transmittance of the second display region is not affected, thereby normal light transmission is not affected. While light propagation on the non-display side is reduced, an amount of light emitted on the display side can be increased, so that a luminous efficiency and brightness of the second display region can be increased.

FIG. 13 is another cross-sectional view of a partition of a second display region according to at least one embodiment of the present disclosure. In some examples, as shown in FIG. 13, an anode layer of a light emitting structure layer is located on a side of the pixel definition layer 44 away from the base substrate 100. For example, an anode 121 of a second light emitting element 12a may be located within a pixel opening formed in the pixel definition layer 44, and an orthographic projection of the anode 121 of the second light emitting element 12a on the base substrate 100 may cover an orthographic projection of the pixel opening on the base substrate 100, so that the anode 121 may be in a groove shape. A sidewall of the anode 121 covering a side surface of the pixel opening may serve as a reflective layer for reflecting light emitted from the second light emitting element 12a, so that the emitted light is reflected to a display side rather than being refracted to the non-display side, thereby improving the progressive dark circle. While light propagation on the non-display side is reduced, the amount of light emitted on the display side can be increased, so that the luminous efficiency and brightness of the second display region can be increased. With regard to remaining structures of the display substrate in this embodiment, reference may be made to the description of the above-mentioned embodiments, and will not be repeated here.

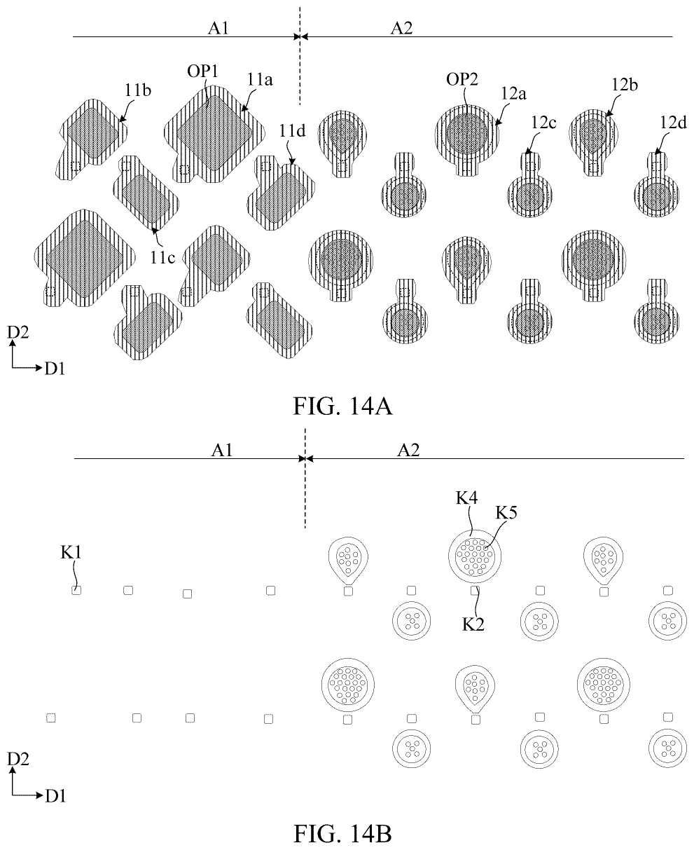

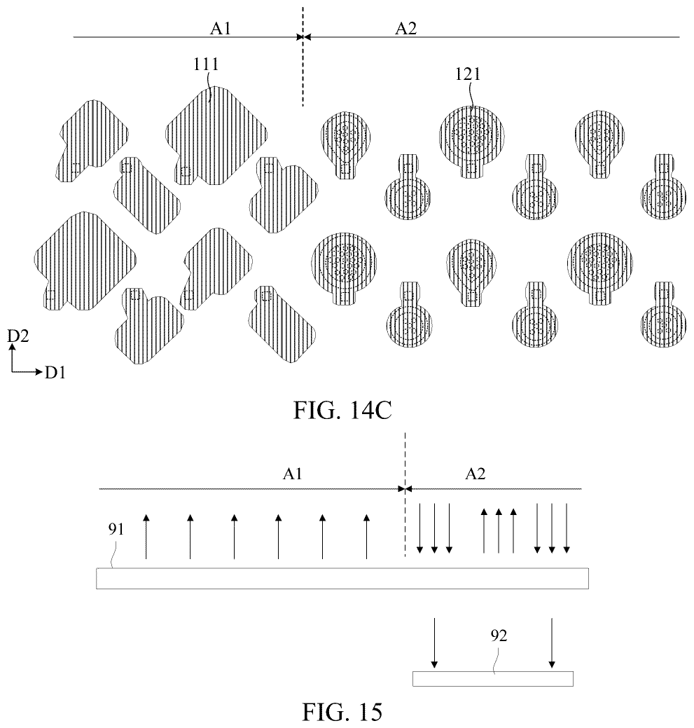

FIG. 14A is a schematic top view of a partition of a display substrate according to at least one embodiment of the present disclosure. FIG. 14B is a schematic diagram of the display substrate after a ninth insulation layer is formed in FIG. 14A. FIG. 14C is a schematic diagram of the display substrate after an anode layer is formed in FIG. 14A. In this example, a first organic insulation layer may serve as the ninth insulation layer.

In some examples, the description is made by taking the first light emitting element 11a emitting light of the first color and the second light emitting element 12a emitting light of the first color as an example. As shown in FIG. 14B, a ninth insulation layer of the first display region A1 may be provided with a first anode via K1. A ninth insulation layer within the first anode via K1 may be removed to expose a fourth anode connection electrode. A ninth insulation layer of the second display region A2 may be provided with a second anode via K2, and an annular groove K4. A second anode via K2 and an annular groove K4 corresponding to the second light emitting element may be not communicated. A ninth insulation layer within the second anode via K2 is removed to expose a surface of the third transparent conductive layer. A ninth insulation layer within the annular groove K4 may be removed completely to expose a surface of an eighth insulation layer, or may be removed partially.

In some examples, the ninth insulation layer of the second display region A2 may further be provided with a plurality of assisted holes K5. The plurality of assisted holes K5 may be located within the annular groove K4. For example, the plurality of assisted holes K5 may be uniformly arranged within the annular groove K4. A quantity of the assisted holes K5 in the annular groove K4 is not limited in this example.

In some examples, as shown in FIG. 14C, an anode layer of the first display region A1 may at least include an anode 111 of the first light emitting element 11a. The anode 111 of the first light emitting element 11a may be electrically connected with a fourth anode connection electrode of the third transparent conductive layer through the first anode via K1. An anode layer of the second display region A2 may at least include an anode 121 of the second light emitting element 12a. The anode 121 of the second light emitting element 12a may be electrically connected with a fourth anode connection electrode or a third transparent conductive line located in the third transparent conductive layer through the second anode via K2. An orthographic projection of the anode 121 of the second light emitting element 12a on the base substrate may cover orthographic projections of the second anode via K2, the annular groove K4, and the plurality of assisted holes K5 located within the annular groove K4 on the base substrate.

In some examples, as shown in FIG. 14A, a pixel definition layer of the first display region A1 is provided with a first pixel opening OP1, and a pixel definition layer within the first pixel opening OP1 is removed to expose a surface of the anode 111. A pixel definition layer of the second display region A2 is provided with a second pixel opening OP2, and a pixel definition layer 92 within the second pixel opening OP2 is removed to expose a surface of the anode 121. An orthographic projection of the second pixel opening OP2 on the base substrate may be overlapped with an orthographic projection of the annular groove K4 on the base substrate. The orthographic projection of the second pixel opening OP2 on the base substrate may cover orthographic projections of a plurality of assisted holes K5 within the annular groove K4 on the base substrate.

In this example, the ninth insulation layer of the second display region is provided with the annular groove and the assisted holes, which can reduce the refraction of the ninth insulation layer to the light emitted from the second light emitting element, facilitate emitting the light of the second light emitting element out from the display side, and improve the luminous efficiency and brightness of the second display region.

With regard to remaining film layer structures of the display substrate in this embodiment, reference may be made to the description of the abovementioned embodiments, which will not be repeated here.

A display apparatus is also provided in at least an embodiment of the present disclosure, which includes the display substrate as described above.

FIG. 15 is a schematic diagram of a display apparatus according to at least one embodiment of the present disclosure. As shown in FIG. 15, the display apparatus according to the embodiment includes a display substrate 91, and a sensor 92 away from a light emitting side of a light emitting structure layer of the display substrate 91. The sensor 92 is located on a side of a non-display face of the display substrate 91. An orthographic projection of the sensor 92 on the display substrate 91 is overlapped with the second display region A2.

In some exemplary implementations, the display substrate 91 may be a flexible OLED display substrate, a QLED display substrate, a Micro-LED display substrate or a Mini-LED display substrate. The display apparatus may be a product having an image (including a still image or a moving image, wherein the moving image may be a video) display function. For example, the display apparatus may be any one of displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display apparatus may be any one of a micro-display, a VR device or an AR device including a micro-display.

The drawings of the present disclosure only involve structures involved in the present disclosure, and other structures may refer to conventional designs. The embodiments of the present disclosure (i.e., features in the embodiments) may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate, comprising a display region, and a peripheral region located at a periphery of the display region; wherein the display region comprises a first display region and a second display region, and the first display region at least partially surrounds the second display region;
a circuit structure layer, which is located on the base substrate and comprises a plurality of pixel circuits, a plurality of initial signal lines, and at least one electrostatic conductive line, wherein the plurality of initial signal lines are electrically connected with the plurality of pixel circuits and extend along a first direction, the at least one electrostatic conductive line extends along a second direction, and the first direction intersects with the second direction; the plurality of pixel circuits are located in the first display region, and the plurality of initial signal lines are at least located in the first display region; the at least one electrostatic conductive line is electrically connected with at least two initial signal lines.

2. The display substrate of claim 1, wherein a plurality of pixel circuits arranged along the first direction are one row of pixel circuits;
the circuit structure layer further comprises a plurality of first signal lines extending along the first direction and electrically connected with the one row of pixel circuits; an orthographic projection of the at least one electrostatic conductive line on the base substrate is overlapped with orthographic projections of the plurality of first signal lines on the base substrate.

3. The display substrate of claim 2, wherein the at least one electrostatic conductive line is located on a side of the plurality of first signal lines close to the base substrate, and the plurality of first signal lines are located on a side of the plurality of initial signal lines close to the base substrate.

4. The display substrate of claim 3, wherein in a direction perpendicular to the display substrate, a circuit structure layer of the first display region at least comprises a semiconductor layer, a first conductive layer, and a second conductive layer, that are sequentially disposed on the base substrate; the semiconductor layer comprises active layers of transistors of the plurality of pixel circuits; the first conductive layer comprises gates of the transistors of the plurality of pixel circuits, and first capacitor plates of storage capacitors of the plurality of pixel circuits; and the second conductive layer comprises second capacitor plates of the storage capacitors of the plurality of pixel circuits; and
the at least one electrostatic conductive line is located on the semiconductor layer, at least two first signal lines of the plurality of first signal lines are located on the first conductive layer, and the plurality of initial signal lines are located on the second conductive layer.

5. The display substrate of claim 2, wherein the plurality of initial signal lines comprise at least one first initial signal line, and at least one second initial signal line;
the at least one electrostatic conductive line comprises at least one first electrostatic conductive line; and
a first initial signal line and a second initial signal line, that are electrically connected with pixel circuits in a same row, are electrically connected with a same first electrostatic conductive line.

6. The display substrate of claim 5, wherein the first electrostatic conductive line is located on a side of the first initial signal line and the second initial signal line close to the base substrate;
one end of the first electrostatic conductive line is electrically connected with the first initial signal line through a first connection electrode, and another end of the first electrostatic conductive line is electrically connected with the second initial signal line through a second connection electrode; the first connection electrode and the second connection electrode are structures in a same layer, and are located on a side of the first initial signal line and the second initial signal line away from the base substrate.

7. The display substrate of claim 5, wherein an orthographic projection of the first electrostatic conductive line on the base substrate is overlapped with orthographic projections of two first signal lines on the base substrate, the two first signal lines comprise a first scan line and a light emitting control line that are electrically connected with pixel circuits in a same row.

8. The display substrate of claim 1, wherein the plurality of initial signal lines comprise a plurality of first initial signal lines and a plurality of second initial signal lines;
the at least one electrostatic conductive line comprises a second electrostatic conductive line and a third electrostatic conductive line;
the second electrostatic conductive line is electrically connected with the plurality of first initial signal lines, and the third electrostatic conductive line is electrically connected with the plurality of second initial signal lines.

9. The display substrate of claim 8, wherein the second electrostatic conductive line and the third electrostatic conductive line are structures in a same layer, and are located on a side of the first initial signal line and the second initial signal line close to the base substrate;
the second electrostatic conductive line is electrically connected with the first initial signal line through a third connection electrode, and the third electrostatic conductive line is electrically connected with the second initial signal line through a fourth connection electrode; the third connection electrode and the fourth connection electrode are structures in a same layer, and are located on a side of the first initial signal line and the second initial signal line away from the base substrate.

10. The display substrate of claim 8, wherein an orthographic projection of a second electrostatic conductive line connected between two adjacent first initial signal lines on the base substrate is overlapped with orthographic projections of three first signal lines on the base substrate; and
an orthographic projection of a third electrostatic conductive line connected between two adjacent second initial signal lines on the base substrate is overlapped with orthographic projections of three first signal lines on the base substrate.

11. The display substrate of claim 1, wherein the at least one electrostatic conductive line is located on a side of the plurality of initial signal lines away from the base substrate.

12. The display substrate of claim 1, wherein the at least one electrostatic conductive line is located in the peripheral region.

13. The display substrate of claim 1, further comprising: a light emitting structure layer located on a side of the circuit structure layer away from the base substrate; wherein the light emitting structure layer comprises a plurality of first light emitting elements located in the first display region, and a plurality of second light emitting elements located in the second display region; the plurality of pixel circuits comprise a plurality of first pixel circuits, and a plurality of second pixel circuits; at least one first pixel circuit of the plurality of first pixel circuits is electrically connected with at least one first light emitting element of the plurality of first light emitting elements, and at least one second pixel circuit of the plurality of second pixel circuits is electrically connected with at least one second light emitting element of the plurality of second light emitting elements.

14. The display substrate of claim 13, wherein the light emitting structure layer comprises an anode layer, and an anode layer of the second display region comprises an anode of a second light emitting element; the anode of the second light emitting element has a bottom, and a sidewall extending from the bottom toward a side away from the base substrate.

15. The display substrate of claim 14, further comprising at least one first organic insulation layer between the light emitting structure layer and the circuit structure layer, wherein a first organic insulation layer of the second display region has at least one first anode groove;
an orthographic projection of the anode of the second light emitting element on the base substrate covers an orthographic projection of the first anode groove of the first organic insulation layer on the base substrate;
the light emitting structure layer further comprises a pixel definition layer located on a side of the anode layer away from the base substrate, wherein the pixel definition layer is provided with a pixel opening exposing a surface of the anode of the second light emitting element; and
the orthographic projection of the first anode groove of the first organic insulation layer on the base substrate covers an orthographic projection of the pixel opening on the base substrate.

16. The display substrate of claim 14, wherein the light emitting structure layer further comprises a pixel definition layer, at least a partition of the anode layer is located on a side of the pixel definition layer away from the base substrate; the pixel definition layer is provided with a pixel opening, and the orthographic projection of the anode of the second light emitting element on the base substrate covers an orthographic projection of the pixel opening on the base substrate.

17. The display substrate of claim 14, wherein the display substrate further comprises a first organic insulation layer located on a side of the anode layer close to the base substrate and in contact with the anode layer, and the first organic insulation layer is provided with at least one annular groove in the second display region; and
an orthographic projection of the anode of the second light emitting element on the base substrate covers an orthographic projection of the annular groove of the first organic insulation layer on the base substrate.

18. The display substrate of claim 17, wherein the first organic insulation layer is further provided with a plurality of assisted holes within the annular groove, and the orthographic projection of the anode of the second light emitting element on the base substrate covers orthographic projections of the plurality of assisted holes within the annular groove on the base substrate.

19. A display apparatus, comprising the display substrate of claim 1.

20. The display apparatus of claim 19, further comprising a sensor located on a side of a non-display face of the display substrate, wherein an orthographic projection of the sensor on the display substrate is overlapped with the second display region of the display substrate.
